(19) United States
(12) Patent Application Publication
(10) Pub. No.: US 2017/0072659 A1
(43) Pub. Date: Mar. 16, 2017

(54) COVER TAPES AND ASSEMBLIES AND METHOD FOR MAKING

(71) Applicant: 3M INNOVATIVE PROPERTIES COMPANY, St. Paul, MN (US)

(72) Inventors: Audrey A. Sherman, Woodbury, MN (US); Kam Poi Chia, Singapore (SG); Leonard D. Cprek, Lexington, KY (US); Kevin R. Schaffer, Woodbury, MN (US)

(21) Appl. No.: 15/123,303

(22) PCT Filed: Feb. 23, 2015
(86) PCT No.: PCT/US2015/017053

§ 371 Date: Sep. 2, 2016

Related U.S. Application Data
(60) Provisional application No. 61/947,562, filed on Mar. 4, 2014.

(51) Int. Cl. B32B 3/30; B32B 1/02; H01L 21/683; B32B 27/08; B32B 27/32; B32B 27/36; C09J 7/02; B32B 7/14

(52) U.S. Cl. CPC B32B 3/30; C09J 7/0296; B32B 1/02; B32B 7/14; B32B 27/08; B32B 27/32; B32B 27/365; H01L 21/6836; C09J 177/00

(57) ABSTRACT

Cover tapes for securing electronic parts in a carrier tape are provided. The cover tape includes opposing edges extending along a longitudinal direction of the cover tape orthogonal to a transverse direction, and first and second layers. The first layer is stretch-oriented along the longitudinal direction at a first stretch ratio, and the first and second layers are stretch-oriented along the transverse direction at a second stretch ratio greater than the first stretch ratio. The cover tape further includes a first major surface extending along the longitudinal direction and between the opposing edges, the first major surface including a plurality of linear depressions extending along the longitudinal direction. The cover tape is hand-tearable along each linear depression. Also, assemblies and methods for making cover tapes are provided.

### FIELD

The present invention relates to cover tapes, assemblies, and methods for making such cover tapes and assemblies.

### BACKGROUND

Cover tapes have been used to close or seal substrates such as carrier tapes, and often include perforations or scores in specific locations across the width of the carrier tapes to assist in tear initiation. A disadvantage of prior cover tapes is the need to make tapes having a range of widths to fit different sized substrates. Another disadvantage of certain prior cover tapes is that the cover tapes do not always tear straight longitudinally down the length of the tape.

The need exists for additional embodiments of cover tapes, methods for making them, and cover tape and carrier tape assemblies.

### SUMMARY

The present invention provides novel cover tapes, assemblies including both a cover tape and a carrier tape, and methods for making cover tapes. The tapes and assemblies can be simply made and provide surprising performance.

In a first aspect, multilayer cover tapes for securing electronic parts in a carrier tape of the invention comprise, and in some instances consist essentially of: opposing edges extending along a longitudinal direction of the cover tape orthogonal to a transverse direction; first and second layers, the first layer being stretch-oriented along the longitudinal direction at a first stretch ratio, the first and second layers being stretch-oriented along the transverse direction at a second stretch ratio greater than the first stretch ratio; and a first major surface extending along the longitudinal direction and between the opposing edges, the first major surface comprising a plurality of linear depressions extending along the longitudinal direction and covering at least 30% of the first major surface, the cover tape being hand-tearable along each linear depression. Typically the cover tape is in the form of one or more sheets wound into roll form or two or more sheets arranged in a stack. When in roll or stack form, the adhesive on an overlying sheet or portion of tape is in contact with the first side of the tape backing of an underlying sheet or portion of tape.

In a second aspect, multilayer cover tapes for securing electronic parts in a carrier tape of the invention comprise, and in some instances consist essentially of: opposing edges extending along a longitudinal direction of the cover tape orthogonal to a transverse direction; first and second layers, the first layer being stretch-oriented along the longitudinal direction at a first stretch ratio, the first and second layers being stretch-oriented along the transverse direction at a second stretch ratio greater than the first stretch ratio; and a first major surface extending along the longitudinal direction and between the opposing edges, the first major surface comprising a plurality of linear depressions extending along the longitudinal direction, a separation between at least two adjacent linear depressions in the plurality of linear depressions being less than about 500 microns, the cover tape being hand-tearable along each linear depression.

In a third aspect, multilayer cover tapes for securing electronic parts in a carrier tape of the invention comprise, and in some instances consist essentially of: opposing edges extending along a longitudinal direction of the cover tape orthogonal to a transverse direction; first and second layers, the first layer being stretch-oriented along the longitudinal direction at a first stretch ratio, the first and second layers being stretch-oriented along the transverse direction at a second stretch ratio greater than the first stretch ratio; and a first major surface extending along the longitudinal direction and between the opposing edges, the first major surface comprising a plurality of linear depressions extending along the longitudinal direction, a separation between at least two adjacent linear depressions in the plurality of linear depressions being less than about 500 microns, the linear depressions forming a periodic pattern along the transverse direction, the cover tape being hand-tearable along each linear depression.

In a fourth aspect, multilayer cover tapes for securing electronic parts in a carrier tape of the invention comprise, and in some instances consist essentially of: first and second layers, the first layer being stretch-oriented along the longitudinal direction at a first stretch ratio, the first and second layers being stretch-oriented along an orthogonal transverse direction at a second stretch ratio greater than the first stretch ratio; a plurality of linear depressions extending along a length of the cover tape; and an adhesive layer, the cover tape being hand-tearable along each linear depression, such that hand-tearing the cover tape along at least one first depression tears the adhesive layer, and hand-tearing the cover tape along at least one second depression does not tear the adhesive layer.

In a fifth aspect, multilayer cover tapes for securing electronic parts in a carrier tape of the invention comprise, and in some instances consist essentially of: opposing edges extending along a longitudinal direction of the cover tape orthogonal to a transverse direction; first and second layers, the first layer being stretch-oriented along the longitudinal direction at a first stretch ratio, the first and second layers being stretch-oriented along the transverse direction at a second stretch ratio smaller than the first stretch ratio; and a first major surface extending along the longitudinal direction and between the opposing edges, the first major surface comprising a plurality of linear depressions extending along the longitudinal direction and covering at least 30% of the first major surface, the cover tape being hand-tearable along each linear depression.

In a sixth aspect, assemblies of the invention comprise, and in some instances consist essentially of: a carrier tape extending along a longitudinal direction and comprising a central portion disposed adjacent a side portion, the central portion comprising a plurality of spaced apart pockets formed therein; and a cover tape extending along the longitudinal direction and covering the central portion of the carrier tape, the cover tape being adhered to the side portion of the carrier tape and comprising a plurality of linear depressions extending along the longitudinal direction, at least some of the linear depressions being in a region of the cover tape corresponding to the side portion of the carrier tape, at least some of the linear depressions being in a region of the cover tape corresponding to the central portion of the carrier tape.

In a seventh aspect, methods of manufacturing a cover tape for securing electronic parts in a carrier tape of the invention comprise: forming a first layer; stretch-orienting the first layer along a longitudinal direction at a first stretch ratio; forming a second layer on the first layer; stretch-orienting the first and second layers along an orthogonal transverse direction at a greater second stretch ratio; and forming a plurality of linear depressions on a first major surface of the first or second layer along the longitudinal direction, the plurality of linear depressions covering at least 30% of the major surface.

In an eighth aspect, cover tapes for securing electronic parts in a carrier tape of the invention comprise, and in some instances consist essentially of: a first layer comprising opposing edges extending along a longitudinal direction of the cover tape orthogonal to a transverse direction and a first major surface extending along the longitudinal direction; a plurality of protruding ribs disposed on the first major surface, the plurality of protruding ribs extending along the longitudinal direction and located between the opposing edges; and first and second lines of adhesive disposed on the first major surface or on a second major surface opposing the first major surface, the first and second lines of adhesive each extending along the longitudinal direction and each located between the opposing edges. The cover tape is stretch-oriented along the longitudinal direction and hand-tearable between each protruding rib.

In a ninth aspect, assemblies of the invention comprise, and in some instances consist essentially of: a carrier tape extending along a longitudinal direction and comprising a central portion disposed adjacent a side portion, the central portion comprising a plurality of spaced apart pockets formed therein; and a cover tape extending along the longitudinal direction and covering the central portion of the carrier tape, the cover tape being adhered to the side portion of the carrier tape and comprising a plurality of protruding ribs extending along the longitudinal direction, at least some of the protruding ribs being in a region of the cover tape corresponding to the side portion of the carrier tape, at least some of the protruding ribs being in a region of the cover tape corresponding to the central portion of the carrier tape.

In accordance with the invention, the cover tape comprises depressions or protruding ribs, as opposed to scores or perforations. An advantage of eliminating scores and perforations is that there is decreased risk of allowing contamination to pass through such scores or perforations in the cover tape. We have surprisingly found that improved tear performance can be achieved with a simplified cover tape construction that does not utilize scoring or perforations to assist in tear initiation and tear propagation. The invention provides tapes that exhibit desirable performance and properties including easy straight-line hand tearing in the longitudinal direction. Cover tapes of the invention can be easily produced via simple manufacturing operations, enabling high speed, cost effective production. The invention can be used to provide cover tapes for a variety of substrates, including, e.g., packaging electronic components in carrier tapes.

Cover tapes of the invention can be readily torn in straight or substantially straight lines, yet provide sufficient tensile strength to be used in an assembly with a carrier tape. Cover tapes of the invention can be well suited for specific performance applications. Cover tapes of aspects of the invention can be made having a variety of widths without significantly altering the manufacturing of the tapes. These and other advantageous embodiments can be made utilizing the discovery that longitudinal depressions can be formed in specific cover tape materials, as described in detail below.

### BRIEF DESCRIPTION OF THE DRAWINGS

The invention is further explained with reference to the drawing wherein:

FIG. 1 is a schematic perspective view of a portion of an illustrative cover tape of the invention;

FIG. 2 is a schematic cross-sectional view of an illustrative cover tape of the invention;

FIG. 3a is a schematic cross-sectional view of an illustrative assembly of the invention;

FIG. 3b is a schematic perspective view of a portion of an illustrative carrier tape of the invention;

FIGS. 4a-4d are schematic cross-sectional views of illustrative cover tapes of the invention;

FIG. 4e is a schematic perspective view of an illustrative cover tape of the invention;

FIG. 5 is a schematic perspective view of a portion of a partially torn illustrative cover tape of the invention;

FIG. 6 is a schematic cross-sectional view of an illustrative cover tape of the invention;

FIGS. 7a-7b are schematic cross-sectional views of illustrative cover tapes of the invention;

FIG. 8 is a schematic cross-sectional view of an illustrative cover tape of the invention; and

FIG. 9 is a schematic cross-sectional view of an illustrative assembly of the invention.

These figures are not to scale and are intended to be merely illustrative and not limiting.

### DETAILED DESCRIPTION

### Key and Glossary

For the following defined terms, these definitions shall be applied, unless a different definition is given in the claims or elsewhere in this specification.

The term “polymer” will be understood to include polymers, oligomers, copolymers (e.g., polymers formed using two or more different monomers), and combinations thereof, as well as polymers, oligomers, or copolymers that can be formed in a miscible blend by, for example, coextrusion or reaction, including transesterification. Both block and random copolymers are included, unless indicated otherwise.

The term “tape” refers to a ribbon-like relatively long, relatively thin configuration.

The term “hand-tearable” as used herein refers to a material having a tear strength of 65 Newtons (N) or less.

The term “periodic pattern” with respect to the structures of linear depressions refers to a recurring arrangement of the structures.

Unless otherwise indicated, all numbers expressing quantities of ingredients, properties such as molecular weight, reaction conditions, and so forth used in the specification and claims are to be understood as being modified in all instances by the term “about”. Accordingly, unless indicated to the contrary, the numerical parameters set forth in the foregoing specification and attached claims are approximations that can vary depending upon the desired properties sought to be obtained by those skilled in the art utilizing the teachings of the present invention. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviations found in their respective testing measurements.

Weight percent, percent by weight, % by weight, and the like are synonyms that refer to the concentration of a substance as the weight of that substance divided by the weight of the composition and multiplied by 100.

The recitation of numerical ranges by endpoints includes all numbers subsumed within that range (e.g., 1 to 5 includes 1, 1.5, 2, 2.75, 3, 3.80, 4, and 5). As used in this specification and the appended claims, the singular forms “a”, “an”, and “the” include plural referents unless the content clearly dictates otherwise. Thus, for example, reference to a composition containing “a compound” includes a mixture of two or more compounds. As used in this specification and the appended claims, the term “or” is generally employed in its sense including “and/or” unless the content clearly dictates otherwise.

As disclosed above, in a first aspect a multilayer cover tape for securing electronic parts in a carrier tape is provided, the cover tape comprising opposing edges extending along a longitudinal direction of the cover tape orthogonal to a transverse direction, first and second layers, and a first major surface extending along the longitudinal direction and between the opposing edges. The first layer is stretch-oriented along the longitudinal direction at a first stretch ratio and the first and second layers are stretch-oriented along the transverse direction at a second stretch ratio greater than the first stretch ratio. The first major surface comprises a plurality of linear depressions extending along the longitudinal direction and covering at least 30% of the first major surface. The cover tape is hand-tearable along each linear depression.

In a second aspect, a multilayer cover tape for securing electronic parts in a carrier tape is provided, the cover tape comprising opposing edges extending along a longitudinal direction of the cover tape orthogonal to a transverse direction, first and second layers, and a first major surface extending along the longitudinal direction and between the opposing edges.

The first layer is stretch-oriented along the longitudinal direction at a first stretch ratio and the first and second layers are stretch-oriented along the transverse direction at a second stretch ratio greater than the first stretch ratio. The first major surface comprises a plurality of linear depressions extending along the longitudinal direction, a separation between at least two adjacent linear depressions in the plurality of linear depressions being less than about 500 microns. The cover tape is hand-tearable along each linear depression.

In a third aspect, a multilayer cover tape for securing electronic parts in a carrier tape is provided, the cover tape comprising opposing edges extending along a longitudinal direction of the cover tape orthogonal to a transverse direction, first and second layers, and a first major surface extending along the longitudinal direction and between the opposing edges. The first layer is stretch-oriented along the longitudinal direction at a first stretch ratio and the first and second layers are stretch-oriented along the transverse direction at a second stretch ratio greater than the first stretch ratio. The first major surface comprises a plurality of linear depressions extending along the longitudinal direction, a separation between at least two adjacent linear depressions in the plurality of linear depressions being less than about 500 microns, the linear depressions forming a periodic pattern along the transverse direction. The cover tape is hand-tearable along each linear depression.

In a fourth aspect, a multilayer cover tape for securing electronic parts in a carrier tape is provided, the cover tape comprising first and second layers, a plurality of linear depressions extending along a length of the cover tape, and an adhesive layer. The first layer is stretch-oriented along the longitudinal direction at a first stretch ratio and the first and second layers are stretch-oriented along an orthogonal transverse direction at a second stretch ratio greater than the first stretch ratio. The cover tape is hand-tearable along each linear depression, such that hand-tearing the cover tape along at least one first depression tears the adhesive layer, and hand-tearing the cover tape along at least one second depression does not tear the adhesive layer.

In a fifth aspect, a multilayer cover tape for securing electronic parts in a carrier tape is provided, the cover tape comprising opposing edges extending along a longitudinal direction of the cover tape orthogonal to a transverse direction, first and second layers, and a first major surface extending along the longitudinal direction and between the opposing edges. The first layer is stretch-oriented along the longitudinal direction at a first stretch ratio and the first and second layers are stretch-oriented along the transverse direction at a second stretch ratio smaller than the first stretch ratio. The first major surface comprises a plurality of linear depressions extending along the longitudinal direction and covering at least 30% of the first major surface. The cover tape is hand-tearable along each linear depression.

In a sixth aspect an assembly is provided comprising a carrier tape extending along a longitudinal direction and comprising a central portion disposed adjacent a side portion, the central portion comprising a plurality of spaced apart pockets formed therein; and a cover tape extending along the longitudinal direction and covering the central portion of the carrier tape. The cover tape is adhered to the side portion of the carrier tape and comprises a plurality of linear depressions extending along the longitudinal direction, at least some of the linear depressions being in a region of the cover tape corresponding to the side portion of the carrier tape, at least some of the linear depressions being in a region of the cover tape corresponding to the central portion of the carrier tape.

The below description applies to various optional aspects of any one or more of the above aspects.

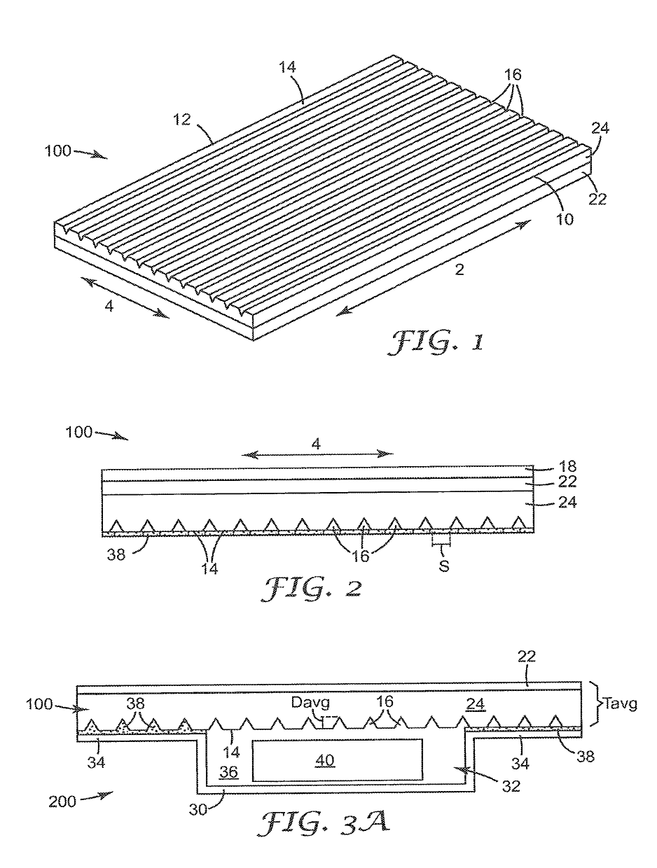

Referring to FIG. 1, a schematic perspective view of a portion of one illustrative cover tape of the invention is provided. The cover tape 100 comprises opposing edges 10 and 12 extending along a longitudinal direction 2 of the cover tape 100 orthogonal to a transverse direction 4. The cover tape 100 comprises first and second layers, and a first major surface 14 extending along the longitudinal direction 2 and between the opposing edges 10 and 12. The first major surface 14 comprises a plurality of linear depressions 16 extending along the longitudinal direction 2. The cover tape 100 is hand-tearable along each linear depression 16. A schematic cross-sectional view of an illustrative cover tape of the invention is provided in FIG. 2. A first layer 22 and the second layer 24 are shown, and in this embodiment the first major surface 14 is provided on the second layer 24. In alternate embodiments, the first major surface is provided on the first layer 22. Moreover, FIG. 2 shows the separation distance, S, between two adjacent linear depressions 16, and an optional conductive layer 18 for static dissipation.

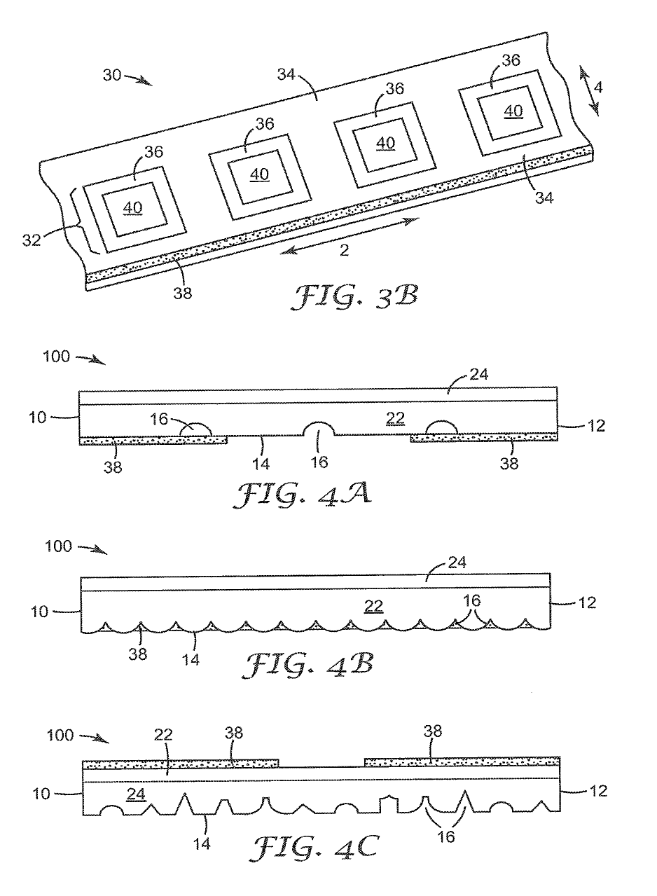

A schematic cross-sectional view of an illustrative assembly of the invention is provided in FIG. 3a, while FIG. 3b is a schematic perspective view of a portion of an illustrative carrier tape of the invention. The assembly 200 comprises a carrier tape 30 extending along a longitudinal direction 2 and comprising a central portion 32 disposed adjacent a side portion 34, the central portion 32 comprising a plurality of spaced apart pockets 36 formed therein; and a cover tape 100 extending along the longitudinal direction 2 and covering the central portion 32 of the carrier tape 30. The cover tape 100 is adhered to the side portion 34 of the carrier tape 30 and comprises a plurality of linear depressions 16 extending along the longitudinal direction 2, at least some of the linear depressions 16 being in a region of the cover tape 100 corresponding to the side portion 34 of the carrier tape 30, at least some of the linear depressions 16 being in a region of the cover tape 100 corresponding to the central portion 32 of the carrier tape 30. In the illustrated embodiment, the cover tape 100 comprises a first layer 22 and a second layer 24, in which the plurality of linear depressions 16 is formed in the second layer 24. Further, adhesive 38 is shown in only a portion of the linear depressions 16. In use, the assembly 200 preferably contains an item 40 disposed in at least one pocket 36, such as an electronic component.

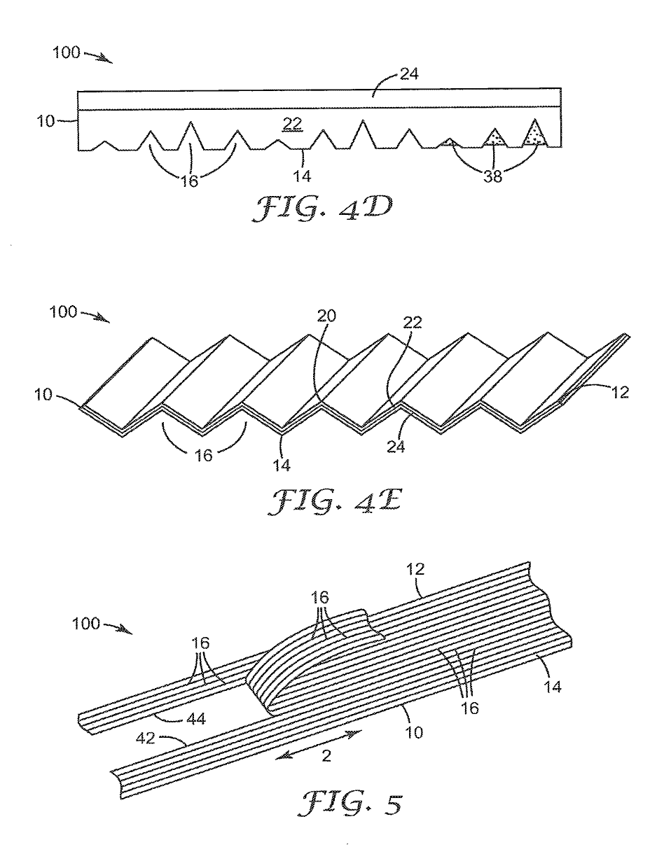

FIGS. 4a through 4e provide schematic cross-sectional views of various illustrative cover tapes of the invention. Referring to FIG. 4a, in certain embodiments, the multilayer cover tape 100 further comprises an adhesive layer 38 covering at least one linear depression 16 in the plurality of linear depressions, and not covering at least one other linear depression 16 in the plurality of linear depressions. Similarly, referring to FIG. 4c, in some embodiments the multilayer cover tape 100 further comprises an adhesive layer 38 directly opposing at least one linear depression 16 in the plurality of linear depressions, and not directly opposing at least one other linear depression 16 in the plurality of linear depressions. Such configurations provide adhesive on locations where the cover tape would be adhered to a substrate (e.g., along or near the opposing edges that extend along the longitudinal direction of the cover tape) but not in locations of the cover tape that do not need to be adhered to a substrate. This is beneficial in certain embodiments for both decreasing adhesive cost by not providing adhesive covering or opposing the entire plurality of linear depressions, and by avoiding undesirable adhesion of the cover tape to any other materials (e.g., a component disposed in a carrier tape to which the cover tape is adhered). Moreover, referring again to FIG. 4c, it has been discovered that the plurality of linear depressions 16 may alternatively be on the side of the cover tape 100 that opposes the adhesive 38.

Advantageously, in many embodiments, a difference between the first and second stretch ratios results in the cover tape being hand-tearable along the longitudinal direction. The first stretch ratio optionally is at most 6, at most 5, or is 1. The second stretch ratio optionally is at least 7, at least 8, at least 9, at least 10, or even at least 11. In certain aspects, a ratio of the second stretch ratio to the first stretch ratio is at least 2 or at least 3. It has been unexpectedly found that although the cover tape is hand-tearable in both the longitudinal and transverse directions, when tearing the cover tape in the longitudinal direction, the tear line tends to continue in the longitudinal direction rather than angling to one side until it tears in the transverse direction (e.g, “cross-tear”), thereby requiring a new tear line to be started in the longitudinal direction. Preferably, each linear depression is centered along a depression axis and has an average depression width, hand-tearing the cover tape along a linear depression resulting in a tear-line, an average deviation of the tear-line from the depression axis of the linear depression being less than about 5 times, or less than about 3 times, or less than about 2 times the average depression width of the linear depression. FIG. 5 provides a schematic perspective view of a portion of a partially torn illustrative cover tape of the invention. The cover tape 100 comprises a plurality of linear depressions 16 extending in a longitudinal direction 2 between the opposing edges 10 and 12, as well as tear lines 42 and 44 each centered on a linear depression 16. In certain aspects, the multilayer cover tape exhibits a tear strength of less than about 250 grams per denier along the longitudinal direction and a tear strength of greater than about 1 grams per denier along the transverse direction. As an alternative to tear strength in the transverse direction, the cover tape optionally exhibits a tensile strength of greater than about 25 psi (0.17 MPa) along the transverse direction.

In most aspects, the cover tape does not have any perforations or scores extending along the longitudinal direction. The term “perforation” as used herein refers to one or more holes formed in a material. A perforation extends through the entire thickness of the material. The term “score” as used herein refers to a cut in a material, which may or may not extend through the entire thickness of the material. In contrast to perforations and scores, the linear depressions disclosed herein do not involve forming opening through the full thickness of the cover tape nor forming cuts in the cover tape. Rather, the linear depressions are preferably embossed into the first major surface of the cover tape.

The cover tape may be embossed by any known method to produce a controlled structure. A structure is controlled if it is repeatable and produced by a structured tool. The structured tool may be, for example, structured release liners or embossing rolls. Generally, the structured tool has a multiplicity of structured features. Each feature should or typically have a dimension normal to it plane of about 2.5 micrometers (0.0001″) to about 375 micrometers (0.015″), for example about 25 micrometers (0.001″) to about 250 micrometers (0.010″), and in some embodiments about 25 micrometers (0.001″) to about 125 micrometers (0.005″). Referring to FIG. 4e, in certain embodiments the embossing process forms groove-shaped linear depressions 16 between the opposing edges 10 and 12 in not only the first major surface 14 of the cover tape 100, but also in a second major surface 20 opposing the first major surface 14. This embossing reshapes both the first layer 22 and the second layer 24 of the cover tape 100. The shape of the features in the structured tool and the cover tapes prepared therefrom can vary. Examples of films suitable for the present application can be found, for example, in U.S. Pat. Nos. 6,838,142; 6,315,851; 6,197,397; and 5,897,930.

In the present application, the structured tool is placed against the film at or above the melting point of the polymer layer that will be structured. The film may be put into a nip, with the nip comprising the structured tool and a roller. In some embodiments, the second roller is chilled to maintain the structural integrity of the multilayer film. Other structuring methods can be found, for example, in U.S. Pat. No. 3,301,741 at Col. 3, lines 37-52 and in WO 2005/052082A.

Referring to FIGS. 4c-4d, in certain embodiments, at least one of the plurality of linear depressions 16 comprises a different depth into the first major surface 14 of the cover tape 100 than at least one other of the plurality of linear depressions 16. Similarly, at least one of the plurality of linear depressions may comprise a variable depth into the first major surface along the longitudinal direction. Moreover, the linear depressions 16 shown in FIG. 4d comprise a periodic pattern with respect to depth of the linear depressions 16 across the transverse direction. At least one of the plurality of linear depressions may comprise a variable depth into the first major surface along the longitudinal direction, the variable depth having a periodic pattern. Alternatively, the linear depressions may form a non-periodic pattern along the transverse direction and/or the longitudinal direction.

Referring again to FIG. 4c, in some embodiments, at least one of the plurality of linear depressions 16 comprises a different shape depressed into the first major surface 14 of the cover tape 100 than at least one other of the plurality of linear depressions. Examples of feature shapes include but are not limited to those selected from the group consisting of hemispheres, prisms (such as square prisms, rectangular prisms, cylindrical prisms and other similar polygonal features), pyramids, ellipses, and grooves. The features may be truncated. Optionally, a shape of the first major surface in between at least two of the plurality of linear depressions comprises a quadrilateral shape, which has been found to assist in preventing cross-tear of the cover tape. In certain embodiments, a separation between at least two adjacent linear depressions in the plurality of linear depressions is less than about 400 microns, or less than about 300 microns, or less than about 200 microns, or less than about 100 microns, or even less than about 50 microns. Preferably, the plurality of linear depressions comprises at least three linear depressions, for instance three linear depressions 16 as illustrated in FIG. 4a. Referring back to FIG. 3a, in some embodiments, an average depth of the plurality of linear depressions 16 is Davg (e.g., 7-35 micrometers), an average thickness of the cover tape 100 is Tavg (e.g., 25-150 micrometers), and a ratio of Tavg to Davg is at least 0.7, or at least 1, or at least 2, or at least 5, at least 8, or even at least 10.

It was surprisingly found that despite the different stretch ratios of the first layer and the second layer, the present invention is operable when the first layer comprises the first major surface or when the second layer comprises the first major surface. In certain embodiments, the linear depressions cover at least 30% of the first major surface, or at least 40%, or at least 50%, or at least 60%, or at least 70%, or at least 80%, or even at least 90% of the first major surface. An advantage to covering a large area or the first major surface includes the ability to form a cover tape having any practical width from the same process and simply cutting a desired tape width, thereby providing a plurality of linear depressions regardless of the particular width of the cover tape. This is in contrast, for instance, to a cover tape having two score lines set in a specific distance from the opposing edges extending along a longitudinal direction of the cover tape, in which the score lines would have to be placed in different locations for every different cover tape width manufactured.

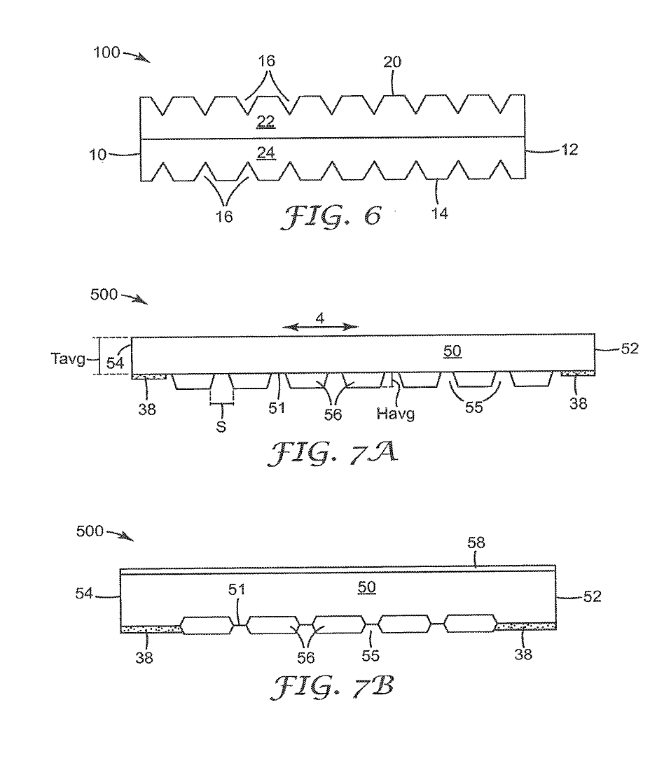

Referring to FIG. 6, in certain embodiments, the multilayer cover tape 100 further comprises a second major surface 20 opposing the first major surface 14 and extending along the longitudinal direction and between the opposing edges 10 and 12, the second major surface 20 comprising a plurality of linear depressions 16 extending along the longitudinal direction.

In some embodiments, the first layer is directly adjacent to the second layer. Alternatively, one or more layers are provided between the first layer and the second layer. Such intermediate layers typically comprise layers providing additional beneficial properties, such as tie layers, barrier layers, antistatic layers, etc., as known in the art. For example and without limitation, a useful functional intermediate layer includes a layer that blocks ultraviolet (UV) radiation. As known to the skilled practitioner, various materials may be employed to prevent degradation by UV radiation, including pigments, dyes, conductive materials, and stabilizers. A variety of stabilizers may be added to a polymeric film intermediate layer to improve its resistance to UV light. Examples of such stabilizers include at least one of ultra violet absorbers (UVA) (e.g., red shifted UV absorbers), hindered amine light stabilizers (HALS), or anti-oxidants. Typically, the polymer of the one or more intermediate layers is a thermoplastic polymer. In certain embodiments, an intermediate layer is provided that is photochromic, changing color upon exposure to UV radiation. Examples of suitable polymers for one or more intermediate layers include polyesters (e.g., polyethylene terephthalate), fluoropolymers, acrylics (e.g., polymethyl methacrylate), silicone polymers (e.g., thermoplastic silicone polymers), styrenic polymers, polyolefins, olefinic copolymers (e.g., copolymers of ethylene and norbornene available as “TOPAS COC” from Topas Advanced Polymers of Florence, Ky.), silicone copolymers, and combinations thereof (e.g., a blend of polymethyl methacrylate and polyvinylidene fluoride).

The materials for the first and second layers are selected in part for their flexibility and strength properties such that the resultant cover tape can be fabricated, handled, and applied as desired as well as provide desired performance. The cover tape typically has a thickness from about 12 to about 75 microns (about 0.47 mils to about 3 mils), though it will be understood that films having thickness outside this range may be used in accordance with the invention if desired.

Cover tapes used herein comprise and may consist essentially of oriented polymeric materials, including thermoplastic compositions. The cover tape typically comprises one or more thermoplastic polymers, especially polyolefin, including polypropylene in specific embodiments. Other polymers may be advantageously employed, especially those polymers which are commonly used for making biaxially oriented films, such as poly(ethylene terephthalate) (PET) and other polyesters. For the purposes of the present invention, the term “polypropylene” is meant to include copolymers comprising at least about 90% propylene monomer units by weight. “Polypropylene” is also meant to include polymer mixtures comprising at least about 75% polypropylene, by weight. Illustrative examples of suitable polymeric layers for use herein include mono-oriented polypropylene (MOPP), sequentially and simultaneously biaxially-oriented polypropylene (BOPP, sBOPP), blown films, e.g., made by any known process including, for example, tenter stretching, single bubble, double bubble, and triple bubble processes, multilayer films, and combinations thereof. The polypropylene used herein is preferably predominantly isotactic, and thus has a chain isotacticity index of at least about 80%, an n-heptane soluble content of less than about 15% by weight, and a density between about 0.86 and 0.92 grams/cm³ measured according to ASTM D1505-96 (“Density of Plastics by the Density-Gradient Technique”). Suitable additional polymers in such mixtures include, but are not limited to, propylene copolymers, polyethylenes, polyolefins comprising monomers having from four to eight carbon atoms, and other polypropylene resins.

Further, the polypropylenes useful in this invention may be copolymers, terpolymers, quaterpolymers, etc., having ethylene monomer units and/or alpha-olefin monomer units with 4-8 carbon atoms. Other suitable co-monomers include, but are not limited to, 1-decene, 1-dodecene, vinylcyclohexene, styrene, allylbenzene, cyclopentene, norbornene, and 5-methylnorbornene. Said co-monomer(s) may be present in an amount so as not to adversely affect the desired properties and characteristics of the films, and tapes described herein, typically their content being less than 10 percent by weight. One suitable polypropylene resin is an isotactic polypropylene homopolymer resin having a melt flow index of 2.5 g/10 minutes, available under the product designation 3374 from Total Petrochemicals Inc. (formerly FINA Oil and Chemical Co.), Dallas, Tex.

Polypropylene for use in the present invention may optionally include, in an amount so as not to adversely affect the desired characteristics and properties described herein, typically between 1 and 40% by weight of a resin, of synthetic or natural origin, having a molecular weight between about 300 and 8000, and having a softening point between about 60° C. and 180° C. Such resin can be chosen from petroleum resins, styrene resins, cyclopentadiene resins, and terpene resins. Petroleum resins typically have, as monomeric constituents, styrene, methylstyrene, vinyltoluene, indene, methylindene, butadiene, isoprene, piperylene, and/or pentylene. Styrene resins typically have, as monomeric constituents, styrene, methylstyrene, vinyltoluene, and/or butadiene. Cyclopentadiene resins typically have, as monomeric constituents, cyclopentadiene and optionally other monomers. Terpene resins typically have, as monomeric constituents, pinene, alpha-pinene, dipentene, limonene, myrcene, and camphene. These resins may be partially or fully hydrogenated.

In most embodiments, the first layer comprises a polymer that is at least partially crystalline, and/or the second layer comprises a polymer that is at least partially crystalline. Each of the first layer and the second layer preferably independently comprises polypropylene, polyethylene terephthalate, polyethylene, polyurethane, silicone thermoplastic elastomers, or combinations thereof. In certain embodiments, the first layer comprises a biaxially oriented propylene polymer sheet. A film sheet of the first layer may be biaxailly oriented in any known method, including extruded, biaxially oriented homopolymer polypropylene (BOPP) film. A second film layer typically comprises a polymer having a melting point different than the melting point of the first polymer layer. More particularly, in some embodiments, a melting point of the first layer is less than a melting point of the second layer, for instance the melting point of the second polymer may be at least 0.5° C. higher than that of the biaxially oriented propylene polymer (e.g., 0.5° C. to about 10° C. higher). In other examples, the second polymer has a lower melting point than the biaxially oriented polypropylene layer.

In some embodiments, the second film layer is a longitudinally oriented propylene polymer. In other embodiments, the second film is a polyethylene. The second polymer film can be coated onto the biaxially oriented polypropylene, or may be co-extruded with the polypropylene and tentered with the propylene. A ratio of an average thickness of the second layer to an average thickness of the first layer is optionally at least 1.5. One specific embodiment of a film that can be employed in aspects of the present invention is found in U.S. Pat. No. 3,887,745 to Yoshii et al., which is incorporated by reference herein. Many materials suitable for use in the cover tapes of the invention are readily available commercially. For instance, numerous biaxially oriented polypropylene (“BOPP”) films are available commercially. Illustrative examples of suitable biaxially oriented polypropylene films for use in the invention include:
1. BOPP TT 30, TT35, or TT 40 gauge non-heat sealable film; BOPP BA 30, BA35, or BA 40 gauge heat sealable film; IM-BOPP or CI-BOPP, metalized film with optional heat sealable layers; PL or PCS BOPP, white cavitated film with optional metalized layer and optional heat sealable layers; all from AmTopp Division of Interplast Group, Livingston N.J.
2. 2578 BOPP, YT62 BOPP, YM17S BOPP and 2500H BOPP films, from Toray Plastics America, North Kingstown R.I.
3. PROPAFILM™ MVU15 and PROPAFILM™ RB35 white coextruded film, from Innovia Films Inc, Atlanta Ga.
4. OPT Film grade BOPP, from YemChio Co. Ltd., Tapei, Taiwan.

Polymeric layers of the present invention may optionally include additives and other components as is known in the art. For example, the layers or component members thereof may contain fillers, pigments and other colorants, antiblocking agents, lubricants, plasticizers, processing aids, antistatic agents, nucleating agents, antioxidants and heat stabilizing agents, ultraviolet-light stabilizing agents, and other property modifiers. Fillers and other additives are preferably added in an amount selected so as not to adversely affect the properties attained by the preferred embodiments described herein.

Illustrative examples of organic fillers include organic dyes and resins, as well as organic fibers such as nylon and polyimide fibers, and inclusions of other, optionally crosslinked, polymers such as polyethylene, polyesters, polycarbonates, polystyrenes, polyamides, halogenated polymers, polymethyl methacrylate, cyclo-olefin polymers, and the like. Illustrative examples of inorganic fillers include pigments, fumed silica and other forms of silicon dioxide, silicates such as aluminum silicate or magnesium silicate, kaolin, talc, sodium aluminum silicate, potassium aluminum silicate, calcium carbonate, magnesium carbonate, diatomaceous earth, gypsum, aluminum sulfate, barium sulfate, calcium phosphate, aluminum oxide, titanium dioxide, magnesium oxide, iron oxides, carbon fibers, carbon black, graphite, glass beads, glass bubbles, mineral fibers, clay particles, metal particles, and the like.

In some applications it may be advantageous for voids to form around the filler particles during an orientation process, or use entrained blowing agents to form voids. Organic and inorganic fillers may also be used effectively as antiblocking agents. Alternatively, or in addition, lubricants such as polydimethyl siloxane oils, metal soaps, waxes, higher aliphatic esters, and higher aliphatic acid amides (such as erucamide, oleamide, stearamide, and behenamide) may be employed.

The cover tape may contain antistatic agents, including aliphatic tertiary amines, glycerol monostearates, alkali metal alkanesulfonates, ethoxylated or propoxylated polydiorganosiloxanes, polyethylene glycol esters, polyethylene glycol ethers, fatty acid esters, ethanol amides, mono- and diglycerides, and ethoxylated fatty amines. Similarly, as illustrated in FIG. 2, a conductive layer 18 is optionally included to provide antistatic characteristics to the cover tape. Organic or inorganic nucleating agents may also be incorporated, such as dibenzylsorbitol or its derivatives, quinacridone and its derivatives, metal salts of benzoic acid such as sodium benzoate, sodium bis(4-tert-butyl-phenyl)phosphate, silica, talc, and bentonite.

Antioxidants and heat stabilizers can further be incorporated, including phenolic types (such as pentaerythrityl tetrakis [3-(3,5-di-tert-butyl-4-hydroxyphenyl)propionate] and 1,3,5-trimethyl-2,4,6-tris(3,5-di-tert-butyl-4-hydroxybenzyl)benzene), and alkali and alkaline earth metal stearates and carbonates. Other additives such as flame retardants, ultraviolet-light stabilizers, compatibilizers, antimicrobial agents (e.g., zinc oxide), electrical conductors, and thermal conductors (e.g., aluminum oxide, boron nitride, aluminum nitride, and nickel particles) may also be blended into the polymers used to form the cover tape.

In some embodiments it is preferred that polymer film layers used in this invention are flame treated on the second side to improve subsequent adhesive coating and anchorage. Flame treatment can be performed as described in U.S. Pat. No. 7,635,264 (Strobel et al.) or in Journal of Adhesion Science and Technology 15 (1), 1-21 (2001). For the improvement in adhesion of all types of materials, the optimal flame equivalence ratio is typically about 0.96, which generates a fuel-lean flame. The resulting flame treated PP surface typically have an ASTM D2578-09 test value of about 50 to about 70 mJ/m². Although flame treatment of the surface to be adhesive coated is preferable, for some tape constructions, it may not be necessary to perform a flame treatment. In some instances, it may be possible to achieve adequate adhesive anchorage using only a standard corona discharge treatment applied during film manufacture as is widely practiced in the plastics industry. Suitable polymeric films, flame treated on one side to improve adhesion of adhesive thereto, are readily available commercially for use in the present invention.

The cover tape typically comprises an initial tear strength of less than 65 Newtons (N), or less than 60 N, or less than 50 N, or even less than 45 N. In such embodiments, the adhesive layer comprises a peel force of greater than 65 N. In general, it is advantageous to provide an adhesive layer comprising a peel force greater than an initial tear strength of the cover tape.

The adhesive may be any suitable adhesive as is known in the art. Preferred adhesives are normally hot melt adhesives. Selection of adhesive will be dependent in large part upon the intended use of the resultant tape. Illustrative examples of suitable adhesives include those based on acrylates, rubber resin such as natural rubber, butyl rubber, styrene copolymers, etc., silicones, and combinations thereof. The adhesive may be applied by solution, water-based or hot-melt coating methods. The adhesive can include hot melt-coated formulations, transfer-coated formulations, solvent-coated formulations, and latex formulations, as well as laminating, thermally-activated, and water-activated adhesives and are not limited except so as to provide a desirable balance of tape roll unwind and adhesion properties.

Those skilled in the art will be able to select suitable adhesives for use in the invention, for example and without limitation hot melt adhesives, heat activated adhesives, or pressure sensitive adhesives, dependent in large part upon the desired application. Illustrative tackified rubber hot melt adhesives that are suitable for use in tapes of the invention are disclosed in U.S. Pat. Nos. 4,125,665, 4,152,231, and 4,756,337. Illustrative acrylic hot melt adhesives that are suitable for use in tapes of the invention are disclosed in U.S. Pat. Nos. 4,656,213 and 5,804,610. Further illustrative adhesives that may be applied as hot melt adhesives suitable for use in tapes of the invention are disclosed in U.S. Pat. Nos. 8,492,486, 8,202,934, and 7,084,209.

Heat activated adhesives are non-tacky at room temperature but become tacky and capable of bonding to a substrate at elevated temperatures. These adhesives usually have a Tg (glass transition temperature) or melting point (Tm) above room temperature. When the temperature is elevated above the Tg or Tm, the storage modulus usually decreases and the adhesive becomes tacky. Examples of suitable optically clear heat activated adhesives include polyacrylate hot melt adhesives, polyvinyl butyrals, ethylene vinyl acetate, ionomers, polyolefins, or combinations thereof.

The optically clear heat activated adhesives may be (meth)acrylate-based hot melt adhesives. The hot melt adhesives typically are prepared from (meth)acrylate polymers that have a glass transition temperature (Tg) of greater than room temperature, more typically greater than about 40° C., and are prepared from alkyl (meth)acrylate monomers. Useful alkyl (meth)acrylates (i.e., acrylic acid alkyl ester monomers) include linear or branched monofunctional unsaturated acrylates or methacrylates of non-tertiary alkyl alcohols, the alkyl groups of which have from 4 to 14 and, in particular, from 4 to 12 carbon atoms. Poly(meth)acrylic hot melt adhesives may also contain optional co-monomer components such as, for example, (meth)acrylic acid, vinyl acetate, N-vinyl pyrrolidone, (meth)acrylamide, a vinyl ester, a fumarate, a styrene macromer, alkyl maleates and alkyl fumarates (based, respectively, on maleic and fumaric acid), or combinations thereof.

In some embodiments, the adhesive layer is at least partially formed of polyvinyl butyral. The polyvinyl butyral layer may be formed via known aqueous or solvent-based acetalization process in which polyvinyl alcohol is reacted with butyraldehyde in the presence of an acidic catalyst. In some instances, the polyvinyl butyral layer may include or be formed from polyvinyl butyral that is commercially available from Solutia Incorporated, of St. Louis, Mo., under the trade name “BUTVAR” resin.

In some instances, the polyvinyl butyral layer may be produced by mixing resin and (optionally) plasticizer and extruding the mixed formulation through a sheet die. If a plasticizer is included, the polyvinyl butyral resin may include about 20 to 80 or perhaps about 25 to 60 parts of plasticizer per hundred parts of resin. Examples of suitable plasticizers include esters of a polybasic acid or a polyhydric alcohol. Suitable plasticizers are triethylene glycol bis(2-ethylbutyrate), triethylene glycol di-(2-ethylhexanoate), triethylene glycol diheptanoate, tetraethylene glycol diheptanoate, dihexyl adipate, dioctyl adipate, hexyl cyclohexyl adipate, mixtures of heptyl and nonyl adipates, diisononyl adipate, heptylnonyl adipate, dibutyl sebacate, polymeric plasticizers such as the oil-modified sebacic alkyds, and mixtures of phosphates and adipates such as disclosed in U.S. Pat. No. 3,841,890 and adipates such as disclosed in U.S. Pat. No. 4,144,217.

Examples of suitable ethylene vinyl acetate (EVA) adhesives include a wide range of commercially available EVA hot melt adhesives. Typically these EVA hot melt adhesives have a vinyl acetate content of from about 18-29% by weight of the polymer. The adhesives typically have high amounts of tackifiers and waxes. An exemplary composition is one with 30-40% by weight of EVA polymer, 30-40% by weight of tackifier, 20-30% by weight of wax, and 0.5-1% by weight of stabilizers. Examples of suitable EVA hot melt adhesives are the BYNEL SERIES 3800 resins commercially available from DuPont, Wilmington, Del. (including BYNEL 3810, BYNEL 3859, BYNEL 3860, and BYNEL 3861). A particularly suitable EVA hot melt adhesive is the material available from Bridgestone Corp. Tokyo, JP under the trade name “EVASAFE”. Examples of suitable ionomeric adhesives are the “ionoplast resins”. Ionoplast resins are copolymers of ethylene and unsaturated carboxylic acids, wherein at least a portion of the acid groups in the copolymer have been neutralized to the salt form of the acid. Extruded sheets of ionoplast resins suitable for use in this disclosure are commercially available from DuPont Chemicals, Wilmington, Del., under the trade name “SENTRYGLASS PLUS”.

Examples of suitable polyolefin adhesives include ethylene/α-olefin copolymers. As used herein, the term “ethylene/α-olefin copolymer” refers to polymers comprising a class of hydrocarbons manufactured by the catalytic oligomerization (i.e., polymerization to low-molecular-weight products) of ethylene and linear α-olefin monomers. The ethylene/α-olefin copolymers may be made, for example, with a single site catalyst such as a metallocene catalyst or multi-site catalysts such as Ziegler-Natta and Phillips catalysts. The linear α-olefin monomers typically are 1-butene or 1-octene but may range from C3 to C20 linear, branched or cyclic α-olefin. The α-olefin may be branched but only if the branch is at least alpha to the double bond, such as 3-methyl-1-pentene. Examples of C3-C20 α-olefins include propylene, 1-butene, 4-methyl-1-butene, 1-hexene, 1-octene, 1-dodecene, 1-tetradecene, 1-hexadecene and 1-octadecene. The α-olefins can also contain a cyclic structure such as cyclohexane or cyclopentane, resulting in an α-olefin such as 3-cyclohexyl-1 propene (allyl cyclohexane) and vinyl cyclohexane. Although not α-olefins in the classical sense of the term, for purposes of this disclosure certain cyclic olefins, such as norbornene and related olefins, are α-olefins and can be used. Similarly, styrene and its related olefins (for example, α-methyl styrene) are α-olefins for the purposes of this disclosure. Acrylic and methacrylic acid and their respective ionomers, and acrylates and methacrylates, however are not α-olefins for the purposes of this disclosure. Illustrative ethylene/α-olefin copolymers include ethylene/1-butene, ethylene/1-octene, ethylene/1-butene/1-octene, ethylene/styrene. The polymers can be block or random. Exemplary commercially available low crystalline ethylene/α-olefin copolymers include resins sold under the tradenames “ENGAGE” ethylene/1-butene and ethylene/1-octene copolymers and “FLEXOMER” ethylene/1-hexene copolymer, available from Dow Chemical Co., and homogeneously branched, substantially linear ethylene/α-olefin copolymers such as “TAFMER”, available from Mitsui Petrochemicals Company Limited, and “EXACT”, available from ExxonMobil Corp. As used herein, the term “copolymer” refers to polymers made from at least 2 monomers.

In some of these embodiments, the α-olefin moiety of the ethylene/α-olefin copolymer includes four or more carbons. In some embodiments, the ethylene/α-olefin copolymer is a low crystalline ethylene/α-olefin copolymer. As used herein, the term “low crystalline” means crystallinity (according to method disclosed in ASTM F2625-07) of less than 50% by weight. In some embodiments, the low crystalline ethylene/α-olefin copolymer is a butene α-olefin. In some embodiments the α-olefin of the low crystalline ethylene/α-olefin copolymer has 4 or more carbons.

In some embodiments, the low crystalline ethylene/α-olefin copolymer has a DSC peak melting point of less than or equal to 50° C. As used herein, the term “DSC peak melting point” means a melting point determined by DSC (10°/min) under nitrogen purge as the peak with the largest area under the DSC curve.

Those skilled in the art will be able to readily select rotary rod or other suitable coating techniques for applying adhesive for use in articles of the invention. Selection of the coating method will be dependent in part upon the flow characteristics of the adhesive, desired penetration of adhesive into perforations, etc. Those skilled in the art will be able to readily select suitable methods for applying or coating adhesive on the sheet. Illustrative examples include rotary rod die coating, knife coating, drop die coating, etc. Illustrative examples of rotary rod coating methods that may be used to make tapes of the invention are disclosed in U.S. Pat. Nos. 4,167,914, 4,465,015, and 4,757,782.

To enhance adhesion between the cover tape or carrier tape and the adhesive, adhesion promoting treatment(s) may be applied to the cover tape or carrier tape, e.g., flame treatment under fuel-lean conditions, exposure to corona, chemical primers, etc.

Pressure sensitive adhesives are well known to possess aggressive and permanent tack, adherence with no more than finger pressure, and sufficient ability to hold onto an adherend.

Additionally, the adhesives can contain additives such as tackifiers, plasticizers, fillers, antioxidants, stabilizers, pigments, diffusing materials, curatives, fibers, filaments, and solvents.

In some embodiments, the adhesive optionally can be cured by any suitable method to modify the properties thereof including rendering it less likely to flow. In particular the crosslinking level can be chosen so as to provide a balance of good tape roll unwind and finished adhesive properties. Typical crosslinking can be provided by well known methods such as radiation-induced crosslinking (for example, UV or e-beam); thermally induced crosslinking, chemically reactive crosslinking or combinations thereof.

The adhesive may be applied in any desired amount, and typically is applied to provide a conventional dry coating weight between about 5 to about 100 gsm (g/m²). Thicker adhesive coatings tend to increase probability of causing undesirable increases in unwind force. Too thin coatings are not functional or tend to wet substrate surfaces poorly. Referring to FIG. 4b, in certain embodiments the adhesive 38 is contained entirely within the linear depressions 16. Such a configuration prevents inadvertent adhesion of the cover tape to any other material prior to deliberately adhering the cover tape to a carrier tape. In such embodiments, the adhesive is optionally provided within the full depth of the depressions, or not quite to the first major surface so adjacent adhesive is essentially separated by the embossed grooves.

Referring to FIG. 3a, the adhesive 38 may comprise a layer on the first major surface 14 of the cover tape 100 that may either impinge into one or more linear depressions 16 or substantially adhere only to the first major surface 14. In certain embodiments, the full transverse width of a cover tape is coated with adhesive. In other embodiments, discrete lines of adhesive are coated across the transverse width (and down the longitudinal direction) of the cover tape, for instance in certain aspects the adhesive is optionally coated only between the individual depressions.

In certain embodiments of an assembly, referring to FIG. 3b, a longitudinal adhesive layer 38 is provided on the carrier tape as opposed to being provided on the cover tape.

Pressure sensitive adhesive (PSA) compositions are well known to those of ordinary skill in the art to possess properties including the following: (1) aggressive and permanent tack, (2) adherence with no more than finger pressure, (3) sufficient ability to hold onto an adherend, and (4) sufficient cohesive strength to be cleanly removable from the adherend. Materials that have been found to function well as PSAs are polymers designed and formulated to exhibit the requisite viscoelastic properties resulting in a desired balance of tack, peel adhesion, and shear holding power. Obtaining the proper balance of properties is not a simple process. Pressure-sensitive adhesives useful in the present invention include tackified natural rubbers, synthetic rubbers, tackified styrene block copolymers, polyvinyl ethers, acrylics, poly-o-olefins, and silicones. Illustrative pressure sensitive adhesives that are suitable for use in the invention are described in US Application Publication Nos. 2013/0337260, 2013/0316076, 2012/0295025, 2012/0100326, and 2009/0161058.

The present invention further includes a seventh aspect, which is a method of manufacturing a cover tape for securing electronic parts in a carrier tape. The method comprises forming a first layer; stretch-orienting the first layer along a longitudinal direction at a first stretch ratio; forming a second layer on the first layer; and stretch-orienting the first and second layers along an orthogonal transverse direction at a greater second stretch ratio. The method also comprises forming a plurality of linear depressions on a first major surface of the first or second layer along the longitudinal direction. The plurality of linear depressions covers at least 30% of the major surface.

The first and second layers are formed by any suitable method known in the art, and in some embodiments the first layer and/or the second layer is formed by extrusion. Preferably, the plurality of linear depressions is formed by embossing, as discussed above.

In certain embodiments, the method further comprises forming an adhesive layer covering at least one linear depression in the plurality of linear depressions, and not covering at least one other linear depression in the plurality of linear depressions. Alternatively, the method may further comprise forming an adhesive layer directly opposing at least one linear depression in the plurality of linear depressions, and not directly opposing at least one other linear depression in the plurality of linear depressions.

Following application of adhesive, cover tapes of the invention may be converted to desired configurations using known approaches, e.g., slitting, rolling, etc. Sheets of tape of the invention may be wound into roll form, e.g., one or more sheets of the tape wound about an optional core, or stacked in sheet form.

An assembly is typically formed using known methods for combining cover tapes and carrier tapes. For instance, depositing one or more products into each pocket of the carrier tape, positioning the cover tape over the filled carrier tape, and adhering the two tapes together. When a heat activated adhesive or a hot melt adhesive is employed the adhering usually comprises applying heat and pressure to the cover tape and the carrier tape at the side portions of the carrier tape (e.g., using a heated metal sealing shoe).

The materials, configurations, etc., for the cover tapes formed by the method are as described in detail above with respect to the first through sixth aspects.

The present invention further includes an eighth aspect, which is a cover tape for securing electronic parts in a carrier tape. The cover tape comprises a first layer comprising opposing edges extending along a longitudinal direction of the cover tape orthogonal to a transverse direction and a first major surface extending along the longitudinal direction and a plurality of protruding ribs disposed on the first major surface, the plurality of protruding ribs extending along the longitudinal direction and located between the opposing edges. The cover tape also comprises first and second lines of adhesive disposed on the first major surface or on a second major surface opposing the first major surface, the first and second lines of adhesive each extending along the longitudinal direction and each located between the opposing edges. The cover tape is stretch-oriented along the longitudinal direction and hand-tearable between each protruding rib.

Referring to FIG. 7a, a schematic cross-sectional view of an illustrative cover tape of the invention is provided. FIG. 7a shows a cover tape 500 comprising a first layer 50 comprising opposing edges 52 and 54 extending along a longitudinal direction of the cover tape orthogonal to a transverse direction 4 and a first major surface 51 extending along the longitudinal direction. The cover tape 500 comprises a plurality of protruding ribs 56 disposed on the first major surface 51, the plurality of protruding ribs 56 extending along the longitudinal direction and located between the opposing edges 52 and 54. Further, the cover tape 500 comprises first and second lines of adhesive 38 disposed on the first major surface 51, the first and second lines of adhesive 38 each extending along the longitudinal direction and each located between the opposing edges 52 and 54. Preferably, the cover tape does not have any perforations or scores extending along the longitudinal direction. In an alternate embodiment, the first and second lines of adhesive are disposed on a second major surface opposing the first major surface, each line extending along the longitudinal direction.

The present invention includes a ninth aspect, which is an assembly. The assembly comprises a carrier tape extending along a longitudinal direction and comprising a central portion disposed adjacent a side portion, the central portion comprising a plurality of spaced apart pockets formed therein. The assembly also comprises a cover tape extending along the longitudinal direction and covering the central portion of the carrier tape, the cover tape being adhered to the side portion of the carrier tape and comprising a plurality of protruding ribs extending along the longitudinal direction. At least some of the protruding ribs are in a region of the cover tape corresponding to the side portion of the carrier tape and at least some of the protruding ribs are in a region of the cover tape corresponding to the central portion of the carrier tape.

Referring to FIG. 9, an assembly 600 is illustrated comprising a carrier tape 30 extending along a longitudinal direction and comprising a central portion 32 disposed adjacent a side portion 34, the central portion 32 comprising a plurality of spaced apart pockets 36 formed therein. The assembly 600 further comprises a cover tape 500 extending along the longitudinal direction and covering the central portion 32 of the carrier tape 30, the cover tape 500 being adhered to the side portion 34 of the carrier tape 30 and comprising a plurality of protruding ribs 56 extending along the longitudinal direction. At least some of the protruding ribs 56 are in a region of the cover tape 500 corresponding to the side portion 34 of the carrier tape 30, and at least some of the protruding ribs 56 are in a region of the cover tape 30 corresponding to the central portion 32 of the carrier tape 30. In an alternate embodiment, the cover tape is adhered to the carrier tape such that the protruding ribs are disposed on a major surface of the cover tape opposing the major surface adhered to the cover tape, e.g., the protruding ribs protrude in a direction opposite of the carrier tape.

The below description applies to various optional aspects of one or both of the above eighth and ninth aspects.

The cover tape 500 is stretch-oriented along the longitudinal direction and hand-tearable between each protruding rib 55. The cover tape is typically hand-tearable along the transverse, but not the longitudinal, direction. The cover tape may exhibit a tear strength of less than about 250 grams per denier along the longitudinal direction and a tensile strength of greater than about 150 pounds per square inch (psi) (1.0 megapascals (MPa)) along the transverse direction. In certain embodiments, an average height of the plurality of protruding ribs 56 is Havg (e.g., 1 mil (25.4 micrometers)), an average thickness of the cover tape 500 is Tavg (e.g., 2 mils (50.8 micrometers)), and a ratio of Tavg to Havg is at least 2, at least 3, at least 4, or even at least 5.

Preferably, the first line of adhesive is disposed on the first major surface or the second major surface directly adjacent one opposing edge and the second line of adhesive is disposed on the first major surface directly adjacent the other opposing edge. The amount of adhesive provided on the cover tape may vary. In certain embodiments, the first and second lines of adhesive in combination cover up to 50% of the first major surface, or up to 40% of the first major surface, or up to 30% of the first major surface, or up to 20% of the first major surface, or even up to 10% of the first major surface. The adhesive may be any suitable adhesive as is known in the art, such as disclosed above with respect to the first through sixth aspects.

The first layer typically comprises a polymer that is at least partially crystalline. More particularly, the first layer can be formed from any extrudable film-forming polymeric material. Polymeric materials suitable for the first layer include polyesters, such as polyethylene terephthalate and polybutylene terephthalate; polyolefins, such as polyethylene and polypropylene; vinylidene chloride-vinyl chloride polymers; vinyl chloride polymers, such as copolymers of vinyl chloride and vinyl acetate; polyvinyl alcohols; polyamides, such as nylon; polycarbonates, polystyrenes, and flexible acrylates and methacrylates. The plurality of protruding ribs is formed from an extrudable polymeric material, usually a polymer that is at least partially crystalline, such as polypropylene or polyvinyl alcohol.

Methods for forming the protruding ribs on the first layer include, for instance, the methods disclosed in U.S. Pat. Nos. 5,079,066 and 5,080,957. Briefly, coextrusion is preferably employed, in which a dual manifold is used having a slot orifice for the first layer and a line of closely spaced orifices extending parallel to the elongated side of the slot orifice. The shapes of the closely spaced orifices determine the shape of the ribs after extrusion, such as being circular or quadrilateral in cross-section. A ratio of the thickness of each protruding rib 56 to the thickness of the first layer may range from 2:1 to 0.05:1, or from 1.5:1 to 0.25:1.

In certain embodiments, the cover tape is calendared and comprises a thickness of less than 2.0 mils (50.8 micrometers), or less than 1.8 mils (45.7 micrometers), or even less than 1.6 mils (40.6 micrometers). Optionally, the plurality of protruding ribs is partially embedded in the first major surface, which may result from calendaring processes. Referring to FIG. 7b, a cover tape 500 is illustrated having a plurality of protruding ribs 56 partially embedded in the first major surface 51 of the first layer 50. The cover tape may further comprise a low adhesion backsize layer 58 formed on a second major surface of the first layer.

The protruding ribs may cover at least 40% of the first major surface, or at least 50%, or at least 60%, or at least 70%, or at least 80%, or even at least 90% of the first major surface. A separation between at least two adjacent ribs in the plurality of protruding ribs is preferably less than about 400 microns, or less than about 300 microns, or less than about 200 microns, or less than about 100 microns, or even less than about 50 microns. In most embodiments, the plurality of protruding ribs comprises at least three ribs.

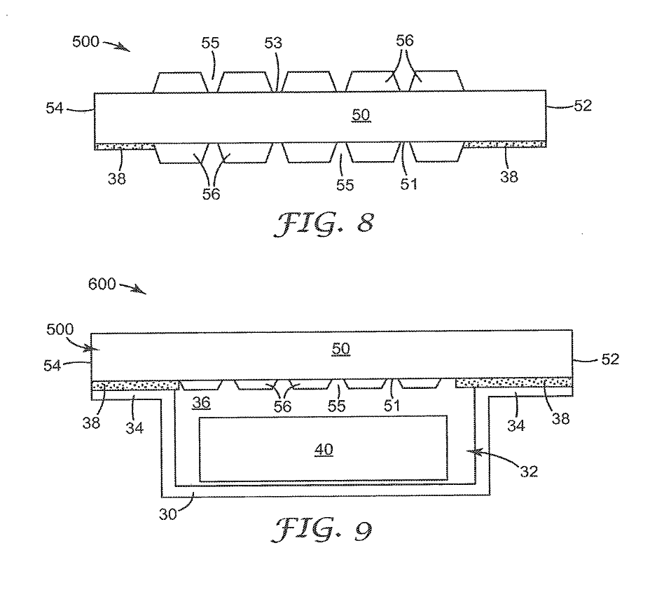

Referring to FIG. 8, in certain embodiments the cover tape 500 further comprises a second major surface 53 opposing the first major surface 51 and extending along the longitudinal direction and between the opposing edges 52 and 54, the second major surface 53 comprising a plurality of protruding ribs 56 extending along the longitudinal direction. The plurality of protruding ribs extending along the longitudinal direction of the second major surface optionally comprises nanoparticles to provide brightness enhancement. Brightness enhancement advantageously provides greater visibility through the cover tape to a product located beneath the cover tape, such as disposed in a carrier tape.

The cover tape typically comprises an initial tear strength of less than 65 Newtons (N), or less than 60 N, or less than 50 N, or even less than 45 N. In such embodiments, the adhesive layer comprises a peel force of greater than 65 N. In general, it is advantageous to provide an adhesive layer comprising a peel force greater than an initial tear strength of the cover tape.

The following items are exemplary embodiments according to aspects of the present invention.

Item 1 is a multilayer cover tape for securing electronic parts in a carrier tape, the cover tape comprising:

opposing edges extending along a longitudinal direction of the cover tape orthogonal to a transverse direction;

first and second layers, the first layer being stretch-oriented along the longitudinal direction at a first stretch ratio, the first and second layers being stretch-oriented along the transverse direction at a second stretch ratio greater than the first stretch ratio; and

a first major surface extending along the longitudinal direction and between the opposing edges, the first major surface comprising a plurality of linear depressions extending along the longitudinal direction and covering at least 30% of the first major surface, the cover tape being hand-tearable along each linear depression.

Item 2 is a multilayer cover tape for securing electronic parts in a carrier tape, the cover tape comprising:

opposing edges extending along a longitudinal direction of the cover tape orthogonal to a transverse direction;

first and second layers, the first layer being stretch-oriented along the longitudinal direction at a first stretch ratio, the first and second layers being stretch-oriented along the transverse direction at a second stretch ratio greater than the first stretch ratio; and

a first major surface extending along the longitudinal direction and between the opposing edges, the first major surface comprising a plurality of linear depressions extending along the longitudinal direction, a separation between at least two adjacent linear depressions in the plurality of linear depressions being less than about 500 microns, the cover tape being hand-tearable along each linear depression.

Item 3 is a multilayer cover tape for securing electronic parts in a carrier tape, the cover tape comprising:

opposing edges extending along a longitudinal direction of the cover tape orthogonal to a transverse direction;

first and second layers, the first layer being stretch-oriented along the longitudinal direction at a first stretch ratio, the first and second layers being stretch-oriented along the transverse direction at a second stretch ratio greater than the first stretch ratio; and

a first major surface extending along the longitudinal direction and between the opposing edges, the first major surface comprising a plurality of linear depressions extending along the longitudinal direction, a separation between at least two adjacent linear depressions in the plurality of linear depressions being less than about 500 microns, the linear depressions forming a periodic pattern along the transverse direction, the cover tape being hand-tearable along each linear depression.

Item 4 is a multilayer cover tape for securing electronic parts in a carrier tape, the cover tape comprising:

first and second layers, the first layer being stretch-oriented along the longitudinal direction at a first stretch ratio, the first and second layers being stretch-oriented along an orthogonal transverse direction at a second stretch ratio greater than the first stretch ratio;

a plurality of linear depressions extending along a length of the cover tape; and

an adhesive layer, the cover tape being hand-tearable along each linear depression, such that hand-tearing the cover tape along at least one first depression tears the adhesive layer, and hand-tearing the cover tape along at least one second depression does not tear the adhesive layer.

Item 5 is a multilayer cover tape for securing electronic parts in a carrier tape, the cover tape comprising:

opposing edges extending along a longitudinal direction of the cover tape orthogonal to a transverse direction;

first and second layers, the first layer being stretch-oriented along the longitudinal direction at a first stretch ratio, the first and second layers being stretch-oriented along the transverse direction at a second stretch ratio smaller than the first stretch ratio; and

a first major surface extending along the longitudinal direction and between the opposing edges, the first major surface comprising a plurality of linear depressions extending along the longitudinal direction and covering at least 30% of the first major surface, the cover tape being hand-tearable along each linear depression.

Item 6 is the multilayer cover tape of any of items 1 to 5 further comprising an adhesive layer covering at least one linear depression in the plurality of linear depressions, and not covering at least one other linear depression in the plurality of linear depressions.

Item 7 is the multilayer cover tape of any of items 1 to 5 further comprising an adhesive layer directly opposing at least one linear depression in the plurality of linear depressions, and not directly opposing at least one other linear depression in the plurality of linear depressions.

Item 8 is the multilayer cover tape of any of items 1 to 5, wherein a difference between the first and second stretch ratios results in the cover tape being hand-tearable along the transverse, but not the longitudinal, direction.

Item 9 is the multilayer cover tape of any of items 1 to 5, wherein an average depth of the plurality of linear depressions is Davg, an average thickness of the cover tape is Tavg, and a ratio of Tavg to Davg is at least 0.7.

Item 10 is the multilayer cover tape of any of items 1 to 4 exhibiting a tear strength of less than about 250 grams per denier along the longitudinal direction and a tear strength of greater than about 1 grams per denier along the transverse direction.

Item 11 is the multilayer cover tape of any of items 1 to 4, wherein the first stretch ratio is at most 6.

Item 12 is the multilayer cover tape of any of items 1 to 4, wherein the second stretch ratio is at least 7.

Item 13 is the multilayer cover tape of any of items 1 to 5, wherein the first stretch ratio is 1.

Item 14 is the multilayer cover tape of any of items 1 to 4, wherein a ratio of the second stretch ratio to the first stretch ratio is at least 2.

Item 15 is the multilayer cover tape of any of items 1 to 5 not having any perforations or scores extending along the longitudinal direction.

Item 16 is the multilayer cover tape of any of items 1 to 5, wherein each linear depression is centered along a depression axis and has an average depression width, hand-tearing the cover tape along a linear depression resulting in a tear-line, an average deviation of the tear-line from the depression axis of the linear depression being less than about 2 times the average depression width of the linear depression.

Item 17 is the multilayer cover tape of any of items 1 to 5, wherein a melting point of the first layer is less than a melting point of the second layer.

Item 18 is the multilayer cover tape of any of items 1 to 5, wherein a ratio of an average thickness of the second layer to an average thickness of the first layer is at least 1.5.

Item 19 is the multilayer cover tape of any of items 1 to 5, wherein the linear depressions cover at least 40% of the first major surface.

Item 20 is the multilayer cover tape of any of items 1 to 5, wherein the linear depressions cover at least 50% of the first major surface.

Item 21 is the multilayer cover tape of any of items 1 to 5, wherein the linear depressions cover at least 60% of the first major surface.

Item 22 is the multilayer cover tape of any of items 1 to 5, wherein the linear depressions cover at least 70% of the first major surface.

Item 23 is the multilayer cover tape of any of items 1 to 5, wherein the linear depressions cover at least 80% of the first major surface.

Item 24 is the multilayer cover tape of any of items 1 to 5, wherein the linear depressions cover up to 90% of the first major surface.

Item 25 is the multilayer cover tape of any of items 1 to 5, wherein the plurality of linear depressions are embossed into the first major surface.

Item 26 is the multilayer cover tape of any of items 1 to 5, wherein the first layer is directly adjacent to the second layer.

Item 27 is the multilayer cover tape of any of items 1 to 5, wherein a separation between at least two adjacent linear depressions in the plurality of linear depressions is less than about 400 microns.

Item 28 is the multilayer cover tape of any of items 1 to 5, wherein a separation between at least two adjacent linear depressions in the plurality of linear depressions is less than about 300 microns.

Item 29 is the multilayer cover tape of any of items 1 to 5, wherein a separation between at least two adjacent linear depressions in the plurality of linear depressions is less than about 200 microns.

Item 30 is the multilayer cover tape of any of items 1 to 5, wherein a separation between at least two adjacent linear depressions in the plurality of linear depressions is less than about 100 microns.

Item 31 is the multilayer cover tape of any of items 1 to 5, wherein a separation between at least two adjacent linear depressions in the plurality of linear depressions is less than about 50 microns.

Item 32 is the multilayer cover tape of any of items 1 to 5, wherein the plurality of linear depressions comprises at least three linear depressions.

Item 33 is the multilayer cover tape of any of items 1 to 5, wherein the first layer comprises a polymer that is at least partially crystalline.

Item 34 is the multilayer cover tape of any of items 1 to 5, wherein the second layer comprises a polymer that is at least partially crystalline.

Item 35 is the multilayer cover tape of any of items 1 to 5, wherein the first layer comprises polypropylene, polyethylene terephthalate, polyethylene, polyurethane, silicone thermoplastic elastomers, or combinations thereof.

Item 36 is the multilayer cover tape of any of items 1 to 5, wherein the second layer comprises polypropylene, polyethylene terephthalate, polyethylene, polyurethane, silicone thermoplastic elastomers, or combinations thereof.

Item 37 is the multilayer cover tape of any of items 1 to 5, wherein at least one of the plurality of linear depressions comprises a different depth into the first major surface than at least one other of the plurality of linear depressions.

Item 38 is the multilayer cover tape of any of items 1 to 5, wherein at least one of the plurality of linear depressions comprises a different shape depressed into the first major surface than at least one other of the plurality of linear depressions.

Item 39 is the multilayer cover tape of any of items 1 to 5, wherein a shape of the first major surface in between at least two of the plurality of linear depressions comprises a quadrilateral shape.

Item 40 is the multilayer cover tape of any of items 1 to 2 or 4 to 5, wherein the linear depressions form a non-periodic pattern along the transverse direction.

Item 41 is the multilayer cover tape of any of items 1 to 5, wherein the first layer comprises the first major surface.

Item 42 is the multilayer cover tape of any of items 1 to 5, wherein the second layer comprises the first major surface.

Item 43 is the multilayer cover tape of any of items 1 to 5 further comprising a second major surface opposing the first major surface and extending along the longitudinal direction and between the opposing edges, the second major surface comprising a plurality of linear depressions extending along the longitudinal direction.

Item 44 is the multilayer cover tape of any of items 1 to 5, wherein at least one of the plurality of linear depressions comprises a variable depth into the first major surface along the longitudinal direction.

Item 45 is the multilayer cover tape of any of items 1 to 5, wherein at least one of the plurality of linear depressions comprises a variable depth into the first major surface along the longitudinal direction, the variable depth having a periodic pattern.

Item 46 is the multilayer cover tape of any of items 1 to 5, wherein the cover tape comprises an initial tear strength of less than 65 Newtons (N).

Item 47 is the multilayer cover tape of any of items 1 to 5, wherein the cover tape comprises an initial tear strength of less than 60 Newtons (N).

Item 48 is the multilayer cover tape of any of items 1 to 5, wherein the cover tape comprises an initial tear strength of less than 50 Newtons (N).

Item 49 is the multilayer cover tape of any of items 1 to 5, wherein the cover tape comprises an initial tear strength of less than 45 Newtons (N).

Item 50 is the multilayer cover tape of item 4, wherein the adhesive layer comprises a peel force of greater than 65 N.

Item 51 is the multilayer cover tape of any of items 1 to 3 or 5, further comprising an adhesive layer comprising a peel force greater than an initial tear strength of the cover tape.

Item 52 is an assembly comprising:

a carrier tape extending along a longitudinal direction and comprising a central portion disposed adjacent a side portion, the central portion comprising a plurality of spaced apart pockets formed therein; and

a cover tape extending along the longitudinal direction and covering the central portion of the carrier tape, the cover tape being adhered to the side portion of the carrier tape and comprising a plurality of linear depressions extending along the longitudinal direction, at least some of the linear depressions being in a region of the cover tape corresponding to the side portion of the carrier tape, at least some of the linear depressions being in a region of the cover tape corresponding to the central portion of the carrier tape.

Item 53 is the assembly of item 52, wherein the cover tape is adhered with an adhesive layer covering at least one linear depression in the plurality of linear depressions, and not covering at least one other linear depression in the plurality of linear depressions.

Item 54 is the assembly of item 52, wherein the cover tape is adhered with an adhesive layer directly opposing at least one linear depression in the plurality of linear depressions, and not directly opposing at least one other linear depression in the plurality of linear depressions.

Item 55 is the assembly of item 52, the cover tape comprising first and second layers, the first layer being stretch-oriented along the longitudinal direction at a first stretch ratio, the first and second layers being stretch-oriented along the transverse direction at a second stretch ratio greater than the first stretch ratio, wherein a difference between the first and second stretch ratios results in the cover tape being hand-tearable along the transverse, but not the longitudinal, direction.

Item 56 is the assembly of item 52, wherein an average depth of the plurality of linear depressions is Davg, an average thickness of the cover tape is Tavg, and a ratio of Tavg to Davg is at least 0.7.

Item 57 is the assembly of item 52 exhibiting a tear strength of less than about 250 grams per denier along the longitudinal direction and a tear strength of greater than about 1 gram per denier along the transverse direction.

Item 58 is the assembly of item 55, wherein the first stretch ratio is at most 6.

Item 59 is the assembly of item 55, wherein the second stretch ratio is at least 7.

Item 60 is the assembly of item 55, wherein the first stretch ratio is 1.

Item 61 is the assembly of item 55, wherein a ratio of the second stretch ratio to the first stretch ratio is at least 2.

Item 62 is the assembly of item 52 not having any perforations or scores extending along the longitudinal direction.

Item 63 is the assembly of item 52, wherein each linear depression is centered along a depression axis and has an average depression width, hand-tearing the cover tape along a linear depression resulting in a tear-line, an average deviation of the tear-line from the depression axis of the linear depression being less than about 2 times the average depression width of the linear depression.

Item 64 is the assembly of item 55, wherein a melting point of the first layer is less than a melting point of the second layer.

Item 65 is the assembly of item 55, wherein a ratio of an average thickness of the second layer to an average thickness of the first layer is at least 1.5.

Item 66 is the assembly of item 52, wherein the linear depressions cover at least 40% of the first major surface.

Item 67 is the assembly of item 52, wherein the linear depressions cover at least 50% of the first major surface.

Item 68 is the assembly of item 52, wherein the linear depressions cover at least 60% of the first major surface.

Item 69 is the assembly of item 52, wherein the linear depressions cover at least 70% of the first major surface.

Item 70 is the assembly of item 52, wherein the linear depressions cover at least 80% of the first major surface.

Item 71 is the assembly of item 52, wherein the linear depressions cover up to 90% of the first major surface.

Item 72 is the assembly of item 52, wherein the plurality of linear depressions is embossed into the first major surface.

Item 73 is the assembly of item 55, wherein the first layer is directly adjacent to the second layer.

Item 74 is the assembly of item 52, wherein a separation between at least two adjacent linear depressions in the plurality of linear depressions is less than about 400 microns.

Item 75 is the assembly of item 52, wherein a separation between at least two adjacent linear depressions in the plurality of linear depressions is less than about 300 microns.

Item 76 is the assembly of item 52, wherein a separation between at least two adjacent linear depressions in the plurality of linear depressions is less than about 200 microns.

Item 77 is the assembly of item 52, wherein a separation between at least two adjacent linear depressions in the plurality of linear depressions is less than about 100 microns.

Item 78 is the assembly of item 52, wherein a separation between at least two adjacent linear depressions in the plurality of linear depressions is less than about 50 microns.

Item 79 is the assembly of item 52, wherein the plurality of linear depressions comprises at least three linear depressions.

Item 80 is the assembly of item 55, wherein the first layer comprises a polymer that is at least partially crystalline.

Item 81 is the assembly of item 55, wherein the second layer comprises a polymer that is at least partially crystalline.

Item 82 is the assembly of item 55, wherein the first layer comprises polypropylene, polyethylene terephthalate, polyethylene, polyurethane, silicone thermoplastic elastomers, or combinations thereof.

Item 83 is the assembly of item 55, wherein the second layer comprises polypropylene, polyethylene terephthalate, polyethylene, polyurethane, silicone thermoplastic elastomers, or combinations thereof.

Item 84 is the assembly of item 52, wherein at least one of the plurality of linear depressions comprises a different depth into a first major surface of the cover tape than at least one other of the plurality of linear depressions.

Item 85 is the assembly of item 52, wherein at least one of the plurality of linear depressions comprises a different shape depressed into a first major surface of the cover tape than at least one other of the plurality of linear depressions.

Item 86 is the assembly of item 52, wherein a shape of a first major surface of the cover tape in between at least two of the plurality of linear depressions comprises a quadrilateral shape.

Item 87 is the assembly of item 52, wherein the linear depressions form a non-periodic pattern along the transverse direction.

Item 88 is the assembly of item 55, wherein the first layer comprises the first major surface.

Item 89 is the assembly of item 55, wherein the second layer comprises the first major surface.

Item 90 is the assembly of item 52 further comprising at least one linear depression extending along the longitudinal direction on a surface opposite of the plurality of linear depressions.

Item 91 is the assembly of item 52, wherein at least one of the plurality of linear depressions comprises a variable depth along the longitudinal direction.

Item 92 is the assembly of item 52, wherein at least one of the plurality of linear depressions comprises a variable depth along the longitudinal direction, the variable depth having a periodic pattern.

Item 93 is the assembly of item 52, wherein the cover tape comprises an initial tear strength of less than 65 Newtons (N).

Item 94 is the assembly of item 52, wherein the cover tape comprises an initial tear strength of less than 60 Newtons (N).

Item 95 is the assembly of item 52, wherein the cover tape comprises an initial tear strength of less than 50 Newtons (N).

Item 96 is the assembly of item 52, wherein the cover tape is adhesive layer is adhered to the carrier tape with a hot melt adhesive.

Item 97 is the assembly of item 52, wherein the adhesion of the cover tape to the carrier tape comprises a peel force of greater than 65 N.

Item 98 is the assembly of item 52, wherein the adhesion of the cover tape to the carrier tape comprises a peel force greater than an initial tear strength of the cover tape.

Item 99 is a method of manufacturing a cover tape for securing electronic parts in a carrier tape, the method comprising:

forming a first layer;

stretch-orienting the first layer along a longitudinal direction at a first stretch ratio;

forming a second layer on the first layer;

stretch-orienting the first and second layers along an orthogonal transverse direction at a greater second stretch ratio; and

forming a plurality of linear depressions on a first major surface of the first or second layer along the longitudinal direction, the plurality of linear depressions covering at least 30% of the major surface.

Item 100 is the method of item 99, wherein the first layer is formed by extrusion.

Item 101 is the method of item 99, wherein the second layer is formed by extrusion.

Item 102 is the method of item 99, wherein the plurality of linear depressions is formed by embossing.

Item 103 is the method of item 99 further comprising forming an adhesive layer covering at least one linear depression in the plurality of linear depressions, and not covering at least one other linear depression in the plurality of linear depressions.

Item 104 is the method of item 99 further comprising forming an adhesive layer directly opposing at least one linear depression in the plurality of linear depressions, and not directly opposing at least one other linear depression in the plurality of linear depressions.

Item 105 is the method of item 99, wherein a difference between the first and second stretch ratios results in the cover tape being hand-tearable along the transverse, but not the longitudinal, direction.

Item 106 is the method of item 99, wherein an average depth of the plurality of linear depressions is Davg, an average thickness of the cover tape is Tavg, and a ratio of Tavg to Davg is at least 0.7.

Item 107 is the method of item 99, the cover tape exhibiting a tear strength of less than about 250 grams per denier along the longitudinal direction and a tear strength of greater than about 1 grams per denier along the transverse direction.

Item 108 is the method of item 99, wherein the first stretch ratio is at most 6.

Item 109 is the method of item 99, wherein the second stretch ratio is at least 7.

Item 110 is the method of item 99, wherein the first stretch ratio is 1.

Item 111 is the method of item 99, wherein a ratio of the second stretch ratio to the first stretch ratio is at least 2.

Item 112 is the method of item 99, wherein the cover tape does not have any perforations or scores extending along the longitudinal direction.

Item 113 is the method of item 99, wherein each linear depression is centered along a depression axis and has an average depression width, hand-tearing the cover tape along a linear depression resulting in a tear-line, an average deviation of the tear-line from the depression axis of the linear depression being less than about 2 times the average depression width of the linear depression.

Item 114 is the method of item 99, wherein a melting point of the first layer is less than a melting point of the second layer.

Item 115 is the method of item 99, wherein a ratio of an average thickness of the second layer to an average thickness of the first layer is at least 1.5.

Item 116 is the method of item 99, wherein the linear depressions cover at least 40% of the first major surface.

Item 117 is the method of item 99, wherein the linear depressions cover at least 50% of the first major surface.

Item 118 is the method of item 99, wherein the linear depressions cover at least 60% of the first major surface.

Item 119 is the method of item 99, wherein the linear depressions cover at least 70% of the first major surface.

Item 120 is the method of item 99, wherein the linear depressions cover at least 80% of the first major surface.

Item 121 is the method of item 99, wherein the linear depressions cover up to 90% of the first major surface.

Item 122 is the method of item 99, wherein the plurality of linear depressions are embossed into the first major surface.

Item 123 is the method of item 99, wherein the first layer is directly adjacent to the second layer.

Item 124 is the method of item 99, wherein a separation between at least two adjacent linear depressions in the plurality of linear depressions is less than about 400 microns.

Item 125 is the method of item 99, wherein a separation between at least two adjacent linear depressions in the plurality of linear depressions is less than about 300 microns.

Item 126 is the method of item 99, wherein a separation between at least two adjacent linear depressions in the plurality of linear depressions is less than about 200 microns.

Item 127 is the method of item 99, wherein a separation between at least two adjacent linear depressions in the plurality of linear depressions is less than about 100 microns.

Item 128 is the method of item 99, wherein a separation between at least two adjacent linear depressions in the plurality of linear depressions is less than about 50 microns.

Item 129 is the method of item 99, wherein the plurality of linear depressions comprises at least three linear depressions.

Item 130 is the method of item 99, wherein the first layer comprises a polymer that is at least partially crystalline.

Item 131 is the method of item 99, wherein the second layer comprises a polymer that is at least partially crystalline.

Item 132 is the method of item 99, wherein the first layer comprises polypropylene, polyethylene terephthalate, polyethylene, polyurethane, silicone thermoplastic elastomers, or combinations thereof.

Item 133 is the method of item 99, wherein the second layer comprises polypropylene, polyethylene terephthalate, polyethylene, polyurethane, silicone thermoplastic elastomers, or combinations thereof.

Item 134 is the method of item 99, wherein at least one of the plurality of linear depressions comprises a different depth into the first major surface than at least one other of the plurality of linear depressions.

Item 135 is the method of item 99, wherein at least one of the plurality of linear depressions comprises a different shape depressed into the first major surface than at least one other of the plurality of linear depressions.

Item 136 is the method of item 99, wherein a shape of the first major surface in between at least two of the plurality of linear depressions comprises a quadrilateral shape.

Item 137 is the method of item 99, wherein the linear depressions form a non-periodic pattern along the transverse direction.

Item 138 is the method of item 99, wherein the first layer comprises the first major surface.

Item 138 is the method of item 99, wherein the second layer comprises the first major surface.

Item 139 is the method of item 99, wherein the cover tape further comprises a second major surface opposing the first major surface and extending along the longitudinal direction and between the opposing edges, the method further comprising forming a plurality of linear depressions on the second major surface extending along the longitudinal direction.

Item 140 is the method of item 99, wherein at least one of the plurality of linear depressions comprises a variable depth into the first major surface along the longitudinal direction.

Item 141 is the method of item 99, wherein at least one of the plurality of linear depressions comprises a variable depth into the first major surface along the longitudinal direction, the variable depth having a periodic pattern.

Item 142 is the method of item 99, wherein the cover tape comprises an initial tear strength of less than 65 Newtons (N).

Item 143 is the method of item 99, wherein the cover tape comprises an initial tear strength of less than 60 Newtons (N).

Item 144 is the method of item 99, wherein the cover tape comprises an initial tear strength of less than 50 Newtons (N).

Item 145 is the method of item 99, wherein the cover tape comprises an initial tear strength of less than 45 Newtons (N).

Item 146 is the method of item 103, wherein the adhesive layer comprises a peel force of greater than 65 N.

Item 147 is the method of item 103, wherein the adhesive layer comprises a peel force greater than an initial tear strength of the cover tape.

Item 148 is a cover tape for securing electronic parts in a carrier tape, the cover tape comprising:

a first layer comprising opposing edges extending along a longitudinal direction of the cover tape orthogonal to a transverse direction and a first major surface extending along the longitudinal direction;

a plurality of protruding ribs disposed on the first major surface, the plurality of protruding ribs extending along the longitudinal direction and located between the opposing edges; and

first and second lines of adhesive disposed on the first major surface or on a second major surface opposing the first major surface, the first and second lines of adhesive each extending along the longitudinal direction and each located between the opposing edges;

wherein the cover tape is stretch-oriented along the longitudinal direction and hand-tearable between each protruding rib.

Item 149 is the cover tape of item 148, wherein the first line of adhesive is disposed on the first major surface directly adjacent one opposing edge and the second line of adhesive is disposed on the first major surface directly adjacent the other opposing edge.

Item 150 is the cover tape of item 148, wherein the first and second lines of adhesive in combination cover up to 50% of the first major surface.

Item 151 is the cover tape of item 148, wherein the first and second lines of adhesive in combination cover up to 40% of the first major surface.

Item 152 is the cover tape of item 148, wherein the first and second lines of adhesive in combination cover up to 30% of the first major surface.

Item 153 is the cover tape of item 148, wherein the first and second lines of adhesive in combination cover up to 20% of the first major surface.

Item 154 is the cover tape of item 148, wherein the first and second lines of adhesive in combination cover up to 10% of the first major surface.

Item 155 is the cover tape of item 148, wherein the plurality of protruding ribs is formed from an extrudable polymeric material.

Item 156 is the cover tape of item 148, wherein the plurality of protruding ribs is formed from polypropylene or polyvinyl alcohol.

Item 157 is the cover tape of item 148 further comprising a low adhesion backsize layer formed on a second major surface of the first layer.

Item 158 is the cover tape of item 148, wherein the cover tape is calendared and comprises a thickness of less than 2.0 mils (50.8 micrometers).

Item 159 is the cover tape of item 148, wherein the cover tape is calendared and comprises a thickness of less than 1.8 mils (45.7 micrometers).

Item 160 is the cover tape of item 148, wherein the cover tape is calendared and comprises a thickness of less than 1.6 mils (40.6 micrometers).

Item 161 is the cover tape of item 148, wherein the plurality of protruding ribs is partially embedded in the first major surface.

Item 162 is the cover tape of item 148, wherein a ratio of the thickness of each protruding rib to the thickness of the first layer ranges from 2:1 to 0.05:1.

Item 163 is the cover tape of item 148, wherein a ratio of the thickness of each protruding rib to the thickness of the first layer ranges from 1.5:1 to 0.25:1.

Item 164 is the cover tape of item 148, wherein the cover tape is hand-tearable along the transverse, but not the longitudinal, direction.

Item 165 is the cover tape of item 148, wherein an average height of the plurality of protruding ribs is Havg, an average thickness of the cover tape is Tavg, and a ratio of Tavg to Havg is at least 2.

Item 166 is the cover tape of item 148 exhibiting a tear strength of less than about 250 grams per denier along the longitudinal direction and a tensile strength of greater than about 150 psi (1.0 MPa) along the transverse direction.

Item 167 is the cover tape of item 148 not having any perforations or scores extending along the longitudinal direction.

Item 168 is the cover tape of item 148, wherein the protruding ribs cover at least 40% of the first major surface.

Item 169 is the cover tape of item 148, wherein the protruding ribs cover at least 50% of the first major surface.

Item 170 is the cover tape of item 148, wherein the protruding ribs cover at least 60% of the first major surface.

Item 171 is the cover tape of item 148, wherein the protruding ribs cover at least 70% of the first major surface.

Item 172 is the cover tape of item 148, wherein the protruding ribs cover at least 80% of the first major surface.

Item 173 is the cover tape of item 148, wherein the protruding ribs cover up to 90% of the first major surface.

Item 174 is the cover tape of item 148, wherein a separation between at least two adjacent ribs in the plurality of protruding ribs is less than about 400 microns.

Item 175 is the cover tape of item 148, wherein a separation between at least two adjacent ribs in the plurality of protruding ribs is less than about 300 microns.

Item 176 is the cover tape of item 148, wherein a separation between at least two adjacent ribs in the plurality of protruding ribs is less than about 200 microns.

Item 177 is the cover tape of item 148, wherein a separation between at least two adjacent ribs in the plurality of protruding ribs is less than about 100 microns.

Item 178 is the cover tape of item 148, wherein a separation between at least two adjacent ribs in the plurality of protruding ribs is less than about 50 microns.

Item 179 is the cover tape of item 148, wherein the plurality of protruding ribs comprises at least three ribs.

Item 180 is the cover tape of item 148, wherein the first layer comprises a polymer that is at least partially crystalline.

Item 181 is the cover tape of item 148, wherein the plurality of ribs comprises a polymer that is at least partially crystalline.

Item 182 is the cover tape of item 148 further comprising a second major surface opposing the first major surface and extending along the longitudinal direction and between the opposing edges, the second major surface comprising a plurality of protruding ribs extending along the longitudinal direction.

Item 183 is the cover tape of item 182, wherein the plurality of protruding ribs extending along the longitudinal direction of the second major surface comprises nanoparticles to provide brightness enhancement.

Item 184 is the cover tape of item 148, wherein the cover tape comprises an initial tear strength of less than 65 Newtons (N).

Item 185 is the cover tape of item 148, wherein the cover tape comprises an initial tear strength of less than 60 Newtons (N).

Item 186 is the cover tape of item 148, wherein the cover tape comprises an initial tear strength of less than 50 Newtons (N).

Item 187 is the cover tape of item 148, wherein the cover tape comprises an initial tear strength of less than 45 Newtons (N).

Item 188 is an assembly comprising:

a carrier tape extending along a longitudinal direction and comprising a central portion disposed adjacent a side portion, the central portion comprising a plurality of spaced apart pockets formed therein; and

a cover tape extending along the longitudinal direction and covering the central portion of the carrier tape, the cover tape being adhered to the side portion of the carrier tape and comprising a plurality of protruding ribs extending along the longitudinal direction, at least some of the protruding ribs being in a region of the cover tape corresponding to the side portion of the carrier tape, at least some of the protruding ribs being in a region of the cover tape corresponding to the central portion of the carrier tape.

Item 189 is the assembly of item 188, wherein the plurality of protruding ribs is formed from an extrudable polymeric material.

Item 190 is the assembly of item 188, wherein the plurality of protruding ribs is formed from polypropylene or polyvinyl alcohol.

Item 191 is the assembly of item 188, wherein the cover tape is calendared and comprises a thickness of less than 2.0 mils (50.8 micrometers).

Item 192 is the assembly of item 188, wherein the cover tape is calendared and comprises a thickness of less than 1.8 mils (45.7 micrometers).

Item 193 is the assembly of item 188, wherein the cover tape is calendared and comprises a thickness of less than 1.6 mils (40.6 micrometers).

Item 194 is the assembly of item 188, wherein the cover tape is hand-tearable along the transverse, but not the longitudinal, direction.

Item 195 is the assembly of item 188, wherein an average height of the plurality of protruding ribs is Davg, an average thickness of the cover tape is Tavg, and a ratio of Tavg to Davg is at least 0.7.

Item 196 is the assembly of item 188 exhibiting a tear strength of less than about 250 grams per denier along the longitudinal direction and a tensile strength of greater than about 150 psi (1.0 MPa) along the transverse direction.

Item 197 is the assembly of item 188, wherein the cover tape does not have any perforations or scores extending along the longitudinal direction.

Item 198 is the assembly of item 188, wherein the protruding ribs cover at least 40% of the cover tape.

Item 199 is the assembly of item 188, wherein the protruding ribs cover at least 50% of the cover tape.

Item 200 is the assembly of item 188, wherein the protruding ribs cover at least 60% of the cover tape.

Item 201 is the assembly of item 188, wherein the protruding ribs cover at least 70% of the cover tape.

Item 202 is the assembly of item 188, wherein the protruding ribs cover at least 80% of the cover tape.

Item 203 is the assembly of item 188, wherein the protruding ribs cover up to 90% of the cover tape.

Item 204 is the assembly of item 188, wherein a separation between at least two adjacent ribs in the plurality of protruding ribs is less than about 400 microns.

Item 205 is the assembly of item 188, wherein a separation between at least two adjacent ribs in the plurality of protruding ribs is less than about 300 microns.

Item 206 is the assembly of item 188, wherein a separation between at least two adjacent ribs in the plurality of protruding ribs is less than about 200 microns.

Item 208 is the assembly of item 188, wherein a separation between at least two adjacent ribs in the plurality of protruding ribs is less than about 100 microns.

Item 209 is the assembly of item 188, wherein a separation between at least two adjacent ribs in the plurality of protruding ribs is less than about 50 microns.

Item 210 is the assembly of item 188, wherein the plurality of protruding ribs comprises at least three ribs.

Item 211 is the assembly of item 188, wherein the cover tape comprises a polymer that is at least partially crystalline.

Item 212 is the assembly of item 188, wherein the plurality of protruding ribs comprises a polymer that is at least partially crystalline.

Item 213 is the assembly of item 188 further comprising a second major surface opposing a first major surface of the cover tape from which the ribs protrude and extending along the longitudinal direction and between the opposing edges, the second major surface comprising a plurality of protruding ribs extending along the longitudinal direction.

Item 214 is the assembly of item 188, wherein the plurality of protruding ribs extending along the longitudinal direction of the second major surface comprises nanoparticles to provide brightness enhancement.

Item 215 is the assembly of item 188, wherein the cover tape comprises an initial tear strength of less than 65 Newtons (N).

Item 216 is the assembly of item 188, wherein the cover tape comprises an initial tear strength of less than 60 Newtons (N).

Item 217 is the assembly of item 188, wherein the cover tape comprises an initial tear strength of less than 50 Newtons (N).

Item 218 is the assembly of item 188, wherein the cover tape comprises an initial tear strength of less than 45 Newtons (N).

### EXAMPLES

The invention will be further understood with reference to the following illustrative examples. These examples are merely for illustrative purposes only and are not meant to be limiting on the scope of the appended claims. All parts, percentages, ratios, etc. in the examples and the rest of the specification are by weight, unless noted otherwise.

### Example 1

### Sample Preparation

Three-layer slabs were coextruded on an extrusion line using either polypropylene (available under tradenames FINA 3376 or UNION CARBIDE 7C50) for the core, polyethylene (available under the tradename DOWLEX 2070G) on the air side, and polyethylene (available under tradenames EXXONMOBIL LD 129.24 or DOWLEX 2070G) on the chill roll side. The slab thickness was 80-150 mils (0.20-0.38 centimeters) with skin thicknesses of 15 to 30% of the total on either side.

Tentering was done on a KARO biaxial stretching machine (commercially available instrument made by Bruckner of Siegsdorf, Germany). Individual 115 millimeter square plaques were cut from the extruded slab and simultaneously stretched to a tenter ratio of 4×4, 6×6, or 7×7 times the original 4 inch clamp distance. The settings were 158° C. oven, 50%/sec stretch rate, 9 Newton preload to prevent sagging during preheat, 180 second preheat, clip temperature 125° C. After tentering, all of the samples maintained interlayer bonding.

Film samples were cut into 10 by 14 inch film samples using a razor blade cutter equipped with fresh blades, and were next embossed on a Wabash platen press. The embossing profile was as follows: 170° C., 5000 lb preload for 5 minutes, 20 ton load for 5 minutes, cool to 50° C. before releasing the load remove liner from tool after 5 minutes of cooling. Patterns included 87 line per inch square linear V-grooves with 10° sidewalls. The film samples fully replicated the tooling pattern. Both the biaxially oriented polypropylene (BOPP) side and the transversely oriented layer could be embossed, although the biaxially oriented side required a slightly higher pressure of a 25-ton load. In both cases some curling was observed, which was believed to be due to rapid cooling. Both film samples curled towards the same side of the film, side B, whether it had the embossed pattern or was still the flat side. It was believed that side B was the transversely oriented layer. In all cases the directional tear by hand feature was retained in the film samples as well.

To these now structured film samples was coated UNI-REZ 2291 Polyamide Resin (obtained from Arizona Chemical, Savannah, Ga.) after dissolving the resin in Isopropanol to prepare a coating containing 15% solids. The coating was applied with a number 12 meyer rod onto the grooved surface of the film samples. The coating was dried for 10 minutes in an oven at 70° C. for 10 minutes. The film was not tacky to the touch and did not adhere to itself.

Next, the film (i.e., cover tape) was heat laminated at 110° C. to a carrier tape and the wells were sealed closed by this top surface film that included a portion of this film extending beyond the carrier tape. The carrier tape was a US008541 Conductive Polycarbonate Carrier 3000 obtained from 3M Company (St. Paul, Minn.), having a width of 12 millimeters (mm), a pitch of 8 mm, pocket length of 6.45 mm, pocket width of 5.13, and pocket depth of 2.11 mm. The result was an assembly including a cover tape and a carrier tape.

Tear

The portion of each cover tape sample that extended beyond the carrier film was then grasped and the film was peeled back by hand at an angle of 120 degrees. The film was observed to tear along either sealed portion of the carrier film, leaving the pocket open to the air again.

Samples could be tested using ASTM D1938-08 “Tear Propagation Resistance (Trouser Tear) of Plastic Film and Thin Sheeting by a Single-Tear Method.” Tear initiation values less than about 65 N are considered “hand tearable.”

### Example 2

### Sample Preparation

A base film prepared as demonstrated in U.S. Pat. Nos. 5,079,066 and 5,080,957. This film was coated with UNI-REZ 2291 Polyamide Resin or UNI-REZ 2678 Hot Melt Polyamide Adhesive, both obtained from Arizona Chemical (Savannah, Ga.) using a rotary rod die with melt temperature of 200° C. to 250° C., to form the cover tape. These cover tapes were slit and heat sealed onto carrier tapes as in Example 1 (i.e., US008541 Conductive Polycarbonate Carrier 3000 obtained from 3M Company). The cover tape was applied to the carrier tape on the V-TEK TM-50 applicator manufactured by V-TEK Inc. (Mankato, Minn.), to form an assembly. The temperature setting was varied between 131° C. to 179° C. for different sample assemblies. The dwell time was 500 milliseconds±200 milliseconds and the pressure was 55 psi±15 psi (0.38 MPa±0.10 MPa) and the speed was at a setting of 150 on the machine. The tear strength of the cover tape in the longitudinal direction was measured on the V-TEK PT-55 Peel Force Tester manufactured by V-TEK Inc. The values measured are given in grams (and Newtons) in Table 1 below for Example 2.

| Arizona Chemical | Application Temperature | Tear in |
|---|---|---|
| Resin on ribbed film | (degrees C.) | grams (Newtons) |
| UNI-REZ 2291 | 131 | 66.7970 (0.655 N) |
| UNI-REZ 2678 | 131 | 60.2260 (0.591 N) |
| UNI-REZ 2291 | 140 | 64.6097 (0.634 N) |
| UNI-REZ 2678 | 140 | 64.6628 (0.634 N) |
| UNI-REZ 2291 | 155 | 25.8276 (0.253 N) |
| UNI-REZ 2678 | 155 | 22.9113 (0.225 N) |

The complete disclosure of all patents, patent documents, and publications cited herein are incorporated by reference. The foregoing detailed description and examples have been given for clarity of understanding only. No unnecessary limitations are to be understood therefrom. The invention is not limited to the exact details shown and described, for variations obvious to one skilled in the art will be included within the invention defined by the claims.

1. A multilayer cover tape for securing electronic parts in a carrier tape, the cover tape comprising:
opposing edges extending along a longitudinal direction of the cover tape orthogonal to a transverse direction;
first and second layers, the first layer being stretch-oriented along the longitudinal direction at a first stretch ratio, the first and second layers being stretch-oriented along the transverse direction at a second stretch ratio greater than the first stretch ratio; and
a first major surface extending along the longitudinal direction and between the opposing edges, the first major surface comprising a plurality of linear depressions extending along the longitudinal direction and covering at least 30% of the first major surface, the cover tape being hand-tearable along each linear depression.

2-5. (canceled)

6. The multilayer cover tape of claim 1 further comprising an adhesive layer covering at least one linear depression in the plurality of linear depressions, and not covering at least one other linear depression in the plurality of linear depressions.

7. The multilayer cover tape of claim 1 further comprising an adhesive layer directly opposing at least one linear depression in the plurality of linear depressions, and not directly opposing at least one other linear depression in the plurality of linear depressions.

8. The multilayer cover tape of claim 1, wherein a difference between the first and second stretch ratios results in the cover tape being hand-tearable along the transverse, but not the longitudinal, direction.

9. The multilayer cover tape of claim 1, wherein an average depth of the plurality of linear depressions is Davg, an average thickness of the cover tape is Tavg, and a ratio of Tavg to Davg is at least 0.7.

10. The multilayer cover tape of claim 1 not having any perforations or scores extending along the longitudinal direction.

11. The multilayer cover tape of claim 1, wherein a melting point of the first layer is less than a melting point of the second layer.

12. The multilayer cover tape of claim 1, wherein the plurality of linear depressions comprises at least three linear depressions.

13. The multilayer cover tape of claim 1, wherein the first layer comprises a polymer that is at least partially crystalline.

14. The multilayer cover tape of claim 1, wherein the cover tape comprises an initial tear strength of less than 65 Newtons (N).

15. The multilayer cover tape of claim 1, further comprising an adhesive layer comprising a peel force greater than an initial tear strength of the cover tape.

16. An assembly comprising:
a carrier tape extending along a longitudinal direction and comprising a central portion disposed adjacent a side portion, the central portion comprising a plurality of spaced apart pockets formed therein; and
a cover tape extending along the longitudinal direction and covering the central portion of the carrier tape, the cover tape being adhered to the side portion of the carrier tape and comprising a plurality of linear depressions extending along the longitudinal direction, at least some of the linear depressions being in a region of the cover tape corresponding to the side portion of the carrier tape, at least some of the linear depressions being in a region of the cover tape corresponding to the central portion of the carrier tape.

17-18. (canceled)

19. A cover tape for securing electronic parts in a carrier tape, the cover tape comprising:
a first layer comprising opposing edges extending along a longitudinal direction of the cover tape orthogonal to a transverse direction and a first major surface extending along the longitudinal direction;
a plurality of protruding ribs disposed on the first major surface, the plurality of protruding ribs extending along the longitudinal direction and located between the opposing edges; and
first and second lines of adhesive disposed on the first major surface or on a second major surface opposing the first major surface, the first and second lines of adhesive each extending along the longitudinal direction and each located between the opposing edges;
wherein the cover tape is stretch-oriented along the longitudinal direction and hand-tearable between each protruding rib.

20. The cover tape of claim 19, wherein the first line of adhesive is disposed on the first major surface directly adjacent one opposing edge and the second line of adhesive is disposed on the first major surface directly adjacent the other opposing edge.

21. (canceled)
